(19) United States
(12) Patent Application Publication
(10) Pub. No.: US 2026/0012150 A1
(43) Pub. Date: Jan. 8, 2026

(54) ATTENUATOR CIRCUIT AND OUTPUT LOAD CIRCUIT

(71) Applicant: Murata Manufacturing Co., Ltd., Magaokakyo-shi (JP)

(72) Inventors: Makoto TABEI, Nagaokakyo-shi (JP); Fumitoshi Deriha, Nagaokakyo-shi (JP)

(21) Appl. No.: 19/329,628

(22) Filed: Sep. 16, 2025

Related U.S. Application Data
(63) Continuation of application No. PCT/JP2024/009643, filed on Mar. 12, 2024.

(30) Foreign Application Priority Data
Mar. 29, 2023 (JP) 2023-053957
Jan. 12, 2024 (JP) 2024-003175

(51) Int. Cl. H03G 1/00; H03F 1/30; H03F 1/56; H03F 3/24; H03G 3/30

(52) U.S. Cl. CPC H03G 1/007; H03F 1/301; H03F 1/56; H03F 3/245; H03G 3/3042; H03F 2200/294; H03G 2201/106

(57) ABSTRACT

An attenuator circuit includes an input/output circuit that is provided at a stage preceding an power amplifier circuit, and a first control circuit that controls a gain of the input/output circuit. The input/output circuit includes at least a first resistor that is electrically connected between an input terminal and an output terminal, and a first FET that is electrically connected between the output terminal and a reference potential point. The first control circuit includes at least a second FET that has an ON resistance that is substantially equal to an ON resistance of the first FET at a time when a gate bias voltage that is the same as a gate bias voltage of the first FET is applied. A gate of the first FET and a gate of the second FET are electrically connected.

### CROSS REFERENCE TO RELATED APPLICATION

This is a continuation of International Application No. PCT/JP2024/009643 filed on Mar. 12, 2024 which claims priority from Japanese Patent Application No. 2023-053957 filed on Mar. 29, 2023 and Japanese Patent Application No. 2024-003175 filed on Jan. 12, 2024. The contents of these applications are incorporated herein by reference in their entireties.

### BACKGROUND OF THE DISCLOSURE

### Field of the Disclosure

The present disclosure relates to an attenuator circuit and an output load circuit.

### Description of the Related Art

An impedance matching circuit or an attenuator circuit is connected to a stage preceding a power amplifier circuit of a power amplifier (PA) or a low noise amplifier (LNA) that performs power amplification of a high frequency signal (for example, Japanese Patent No. 2555926).

### BRIEF SUMMARY OF THE DISCLOSURE

In a CMOS transistor or a bipolar transistor that is used as a power amplifier element of a PA or an LNA, gain varies based on temperature characteristics of mutual conductance (gm) and a current amplification factor (B). Specifically, gain decreases under a high temperature environment. It may be considered that variations in the gain caused by the temperature characteristics of the power amplifier element are canceled out by increasing a driving current of the power amplifier element at a high temperature. However, in this case, the temperature further increases as the driving current increases, and this may cause a degradation of performance of a power amplifier circuit including the power amplifier element and a peripheral circuit element. Furthermore, this may also cause an increase in the operating cost of the power amplifier circuit as a result of an increase in a consumption current at the high temperature.

The present disclosure has been designed in view of the above point, and a possible benefit of the present disclosure is to attain an attenuator circuit capable of suppressing a degradation of performance and compensating for variations in gain caused by temperature characteristics of a power amplifier element.

An attenuator circuit according to an aspect of the present disclosure includes an input/output circuit that is provided at a stage preceding a power amplifier, and a first control circuit that controls a gain of the input/output circuit. The input/output circuit includes at least a first resistor that is electrically connected between an input terminal and an output terminal, and a first FET that is electrically connected between the output terminal and a reference potential point. The first control circuit includes at least a second FET that has an ON resistance that is substantially equal to an ON resistance of the first FET at a time when a gate bias voltage that is the same as a gate bias voltage of the first FET is applied. A gate of the first FET and a gate of the second FET are electrically connected.

With this configuration, by controlling the ON resistance of the second FET, the gate bias voltage of the first FET can be controlled. Thus, insertion loss of the power amplifier can be controlled, and variations in the gain of the power amplifier caused by temperature characteristics of a power amplifier element can be canceled out.

An output load circuit according to an aspect of the present disclosure includes an output matching circuit that is provided at a stage subsequent to a power amplifier, a capacitor and a third FET that are connected in series between an output of the output matching circuit and a reference potential point, and a second control circuit that controls an impedance of the output matching circuit. The second control circuit includes at least a fourth FET that has an ON resistance that is substantially equal to an ON resistance of the third FET at a time when a gate bias voltage that is the same as a gate bias voltage of the third FET is applied. A gate of the third FET and a gate of the fourth FET are electrically connected.

With this configuration, by controlling the ON resistance of the fourth FET, the gate bias voltage of the third FET can be controlled. Thus, an impedance of the output load circuit can be controlled, and the impedance of the output load circuit can be optimized based on temperature characteristics of a power amplifier element.

According to the present disclosure, an attenuator circuit and an output load circuit capable of suppressing a degradation of performance and compensating for variations in gain caused by temperature characteristics of a power amplifier element can be attained.

### BRIEF DESCRIPTION OF THE SEVERAL VIEWS OF THE DRAWINGS

FIG. 1 is a diagram illustrating an example of a schematic configuration of a power amplifier circuit representing an application example of an attenuator circuit according to an embodiment.

FIG. 2A is a block diagram illustrating a first modification of an input/output circuit.

FIG. 2B is a block diagram illustrating a second modification of the input/output circuit.

FIG. 2C is a block diagram illustrating a third modification of the input/output circuit.

FIG. 3 is a block diagram illustrating a configuration example of a first control circuit in Embodiment 1.

FIG. 4 is a block diagram illustrating a configuration example of a variable current source of the first control circuit in Embodiment 1.

FIG. 5 is a block diagram illustrating a configuration example of a PTAT current source.

FIG. 6 is a diagram illustrating a temperature characteristics example of each current in the first control circuit.

FIG. 7 is a diagram illustrating a temperature characteristics example of insertion loss in an input/output circuit.

FIG. 8 is a diagram illustrating a temperature characteristics example of input/output gain in the power amplifier circuit.

FIG. 9 is a block diagram illustrating a configuration example of a first control circuit in Embodiment 2.

FIG. 10 is a block diagram illustrating a configuration example of a variable current source of the first control circuit in Embodiment 2.

FIG. 11 is a block diagram illustrating a configuration example of a first control circuit in Embodiment 3.

FIG. 12 is a block diagram illustrating a configuration example of a variable current source of the first control circuit in Embodiment 3.

FIG. 13 is a diagram illustrating an example of a schematic configuration of a power amplifier circuit representing an application example of an output load circuit according to an embodiment.

FIG. 14 is a block diagram illustrating a modification of an impedance matching circuit.

FIG. 15 is a block diagram illustrating a configuration example of a second control circuit in Embodiment 4.

FIG. 16 is a block diagram illustrating a configuration example of a variable current source of the second control circuit in Embodiment 4.

FIG. 17 is a block diagram illustrating a configuration example of a PTAT current source.

FIG. 18 is a block diagram illustrating a configuration example of a second control circuit in Embodiment 5.

FIG. 19 is a block diagram illustrating a configuration example of a variable current source of the second control circuit in Embodiment 5.

FIG. 20 is a block diagram illustrating a configuration example of a second control circuit in Embodiment 6.

FIG. 21 is a block diagram illustrating a configuration example of a variable current source of the second control circuit in Embodiment 6.

### DETAILED DESCRIPTION OF THE DISCLOSURE

Hereinafter, attenuator circuits according to embodiments will be described in detail with reference to the drawings. The present disclosure is not intended to be limited to the embodiments described below. Each of the embodiments is illustrative and, obviously, components illustrated in different embodiments can be partially replaced or combined. In the second and subsequent embodiments, description of features that are in common with the first embodiment will be omitted and only different features will be described. In particular, similar operational effects achieved by similar configurations will not be described in each embodiment.

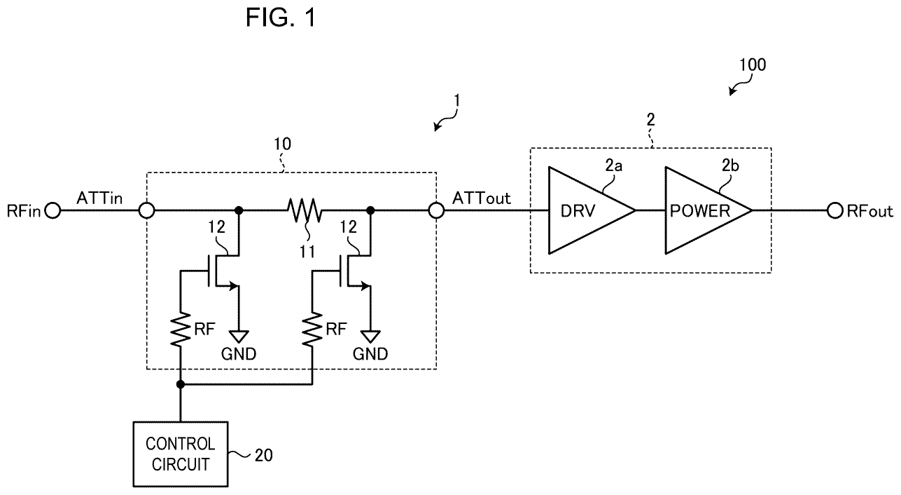

FIG. 1 is a diagram illustrating an example of a schematic configuration of a power amplifier circuit representing an application example of an attenuator circuit according to an embodiment. A power amplifier circuit 100 amplifies a high frequency input signal RFin and outputs a high frequency output signal RFout. In FIG. 1, a power amplifier 2 (PA) with a two-stage configuration including a drive-stage amplifier 2a and a power-stage amplifier 2b is illustrated. An input/output circuit 10 of an attenuator circuit 1 according to an embodiment is provided at a stage preceding the power amplifier 2.

In the present disclosure, the power amplifier 2 is not limited to the two-stage PA illustrated in FIG. 1. For example, the power amplifier 2 may be a one-stage power amplifier or may have a multiple-stage configuration in which three or more stages of amplifiers are connected. Furthermore, the power amplifier 2 is not necessarily a PA. The power amplifier 2 may be, for example, a low noise amplifier (LNA).

For example, the input/output circuit 10 is configured as an impedance matching circuit. In FIG. 1, a so-called II-type impedance matching circuit including a series resistor (first resistor 11) provided between an input terminal ATTin and an output terminal ATTout of the input/output circuit 10 and NMOSFETs (first FETs 12) provided at both ends of the series resistor that are shunt-connected is illustrated. In the present disclosure, the II-type circuit is configured using ON resistance Ron1 of the NMOSFETS (first FETs 12).

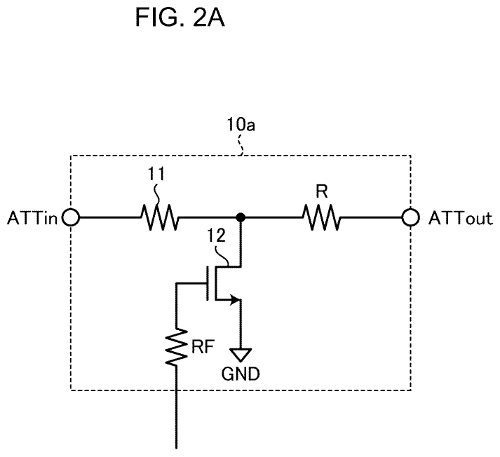

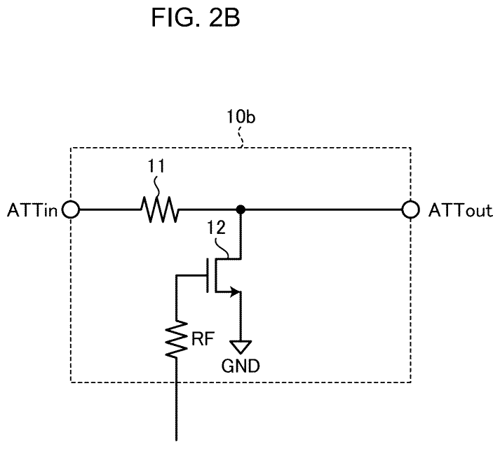

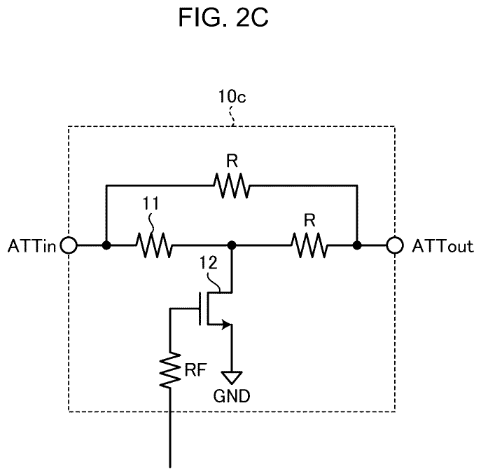

In the present disclosure, the attenuator circuit 1 does not necessarily have the II-type circuit configuration illustrated in FIG. 1. FIGS. 2A, 2B, and 2C are block diagrams illustrating modifications of the input/output circuit. For example, the attenuator circuit 1 may have a configuration including an input/output circuit 10a of a so-called T type illustrated in a first modification in FIG. 2A, may have a configuration including an input/output circuit 10b of a so-called L type illustrated in a second modification in FIG. 2B, or may have a configuration including an input/output circuit 10c of a so-called bridged T type illustrated in a third modification in FIG. 2C. The input/output circuit 10 (10a, 10b, 10c) only needs to have a configuration including at least the first resistor 11 that is electrically connected between the input terminal ATTin and the output terminal ATTout and a first FET 12 that is electrically connected between the output terminal ATTout and a reference potential point GND of a fixed potential (ground potential in FIGS. 1, 2A, 2B, and 2C).

In the example illustrated in FIG. 1, the configuration in which another first FET 12 is connected between the input terminal ATTin and the reference potential point GND is illustrated. In the case where the input/output circuit 10 (10a, 10b, 10c) is configured as an impedance matching circuit, an aspect in which ON resistance of an FET including the first resistor 11 and other resistors R in each circuit is used may also be included. The configuration of the input/output circuit 10 in FIG. 1 will be illustrated below.

As a power amplifier element used in the power amplifier 2, for example, a MOSFET or a bipolar transistor configured using a heterojunction bipolar transistor (HBT) process, a silicon process, or the like is illustrated. The gain of such a MOSFET or a bipolar transistor varies based on temperature characteristics of mutual conductance (gm) and a current amplification factor (B). Specifically, the gain decreases under a high temperature environment. It may be considered that variations in the gain caused by the temperature characteristics of the power amplifier element can be canceled out by increasing the driving current of the power amplifier element at a high temperature. However, in this case, the temperature further increases as the driving current increases, and this may cause a degradation of the performance of the power amplifier circuit including the power amplifier element and a peripheral circuit element. Furthermore, this may also cause an increase in the operating cost of the power amplifier circuit as a result of an increase in the consumption current at the high temperature.

In the present disclosure, insertion loss IL of the input/output circuit 10 is controlled based on the temperature. Specifically, at a high temperature, by increasing the ON resistance Ron1 of the first FET 12 of the input/output circuit 10 compared to that at a low temperature, the insertion loss IL of the input/output circuit 10 is reduced. Thus, variations in the gain of the power amplifier 2 caused by the temperature characteristics of the power amplifier element can be canceled out.

More specifically, the attenuator circuit 1 includes a first control circuit 20 that controls a gate bias voltage for controlling the ON resistance Ron1 of the first FET 12. In each of the embodiments described below, a specific configuration and operation of the first control circuit 20 will be described.

### Embodiment 1

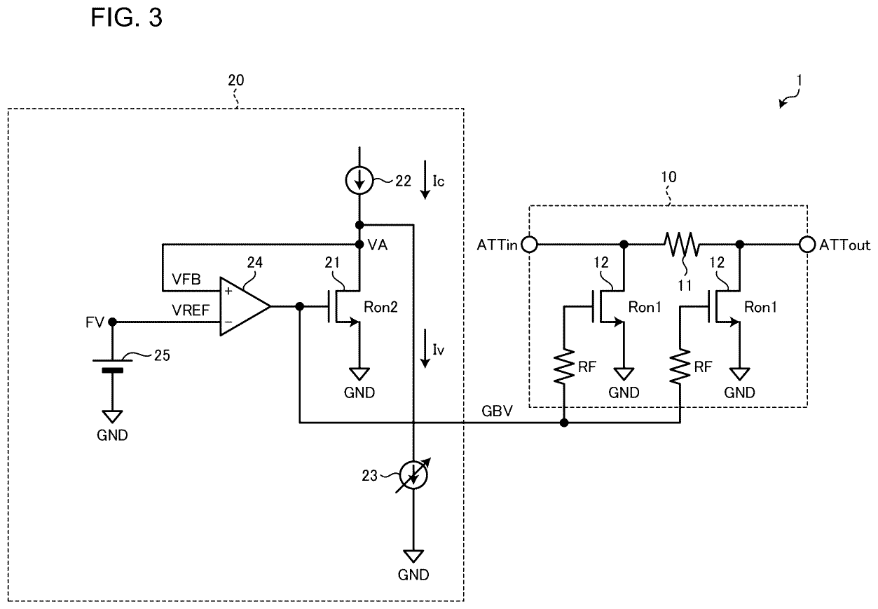

FIG. 3 is a block diagram illustrating a configuration example of a first control circuit in Embodiment 1. In the configuration example in Embodiment 1, the first control circuit 20 includes a second FET 21, a constant current source 22, a variable current source 23, an operational amplifier circuit 24, and a constant voltage source 25.

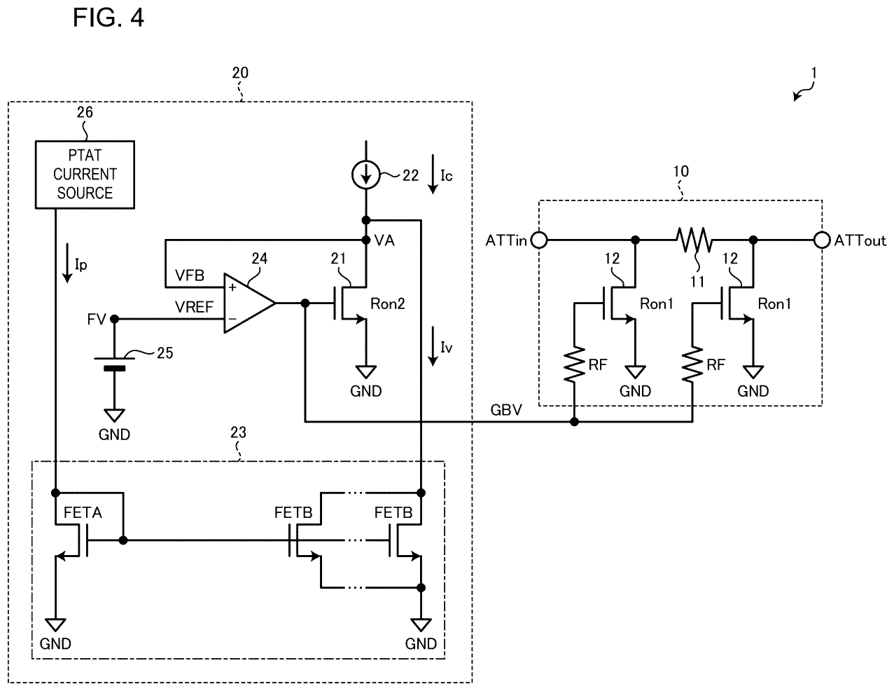

The constant current source 22 supplies a constant current Ic to a variable potential point VA illustrated in FIG. 3. The variable current source 23 is connected between the variable potential point VA and a reference potential point GND. FIG. 4 is a block diagram illustrating a configuration example of the variable current source of the first control circuit in Embodiment 1.

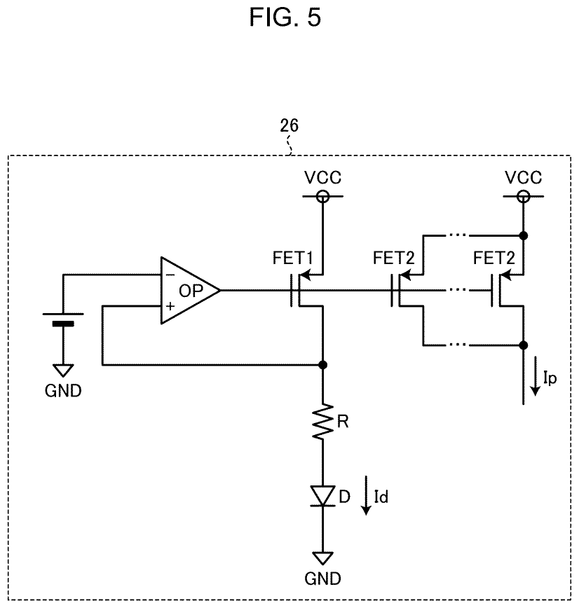

In the configuration example illustrated in FIG. 4, the variable current source 23 is a current mirror circuit. Furthermore, in the configuration example illustrated in FIG. 4, the first control circuit 20 includes a PTAT current source 26 that supplies a variable current Ip to an input of the variable current source 23 (current mirror circuit). FIG. 5 is a block diagram illustrating a configuration example of the PTAT current source.

The PTAT current source 26 is configured to generate a variable current that is proportional to the absolute temperature. In the configuration example illustrated in FIG. 5, the PTAT current source 26 is configured to generate the variable current Ip based on temperature characteristics of a diode D.

In the example illustrated in FIG. 5, an FET 1 and FETs 2 are PMOSFETs that have a substantially equivalent performance. The same voltage VCC is supplied to the FET 1 and the FETs 2. The PTAT current source 26 generates the variable current Ip, which is obtained by multiplying a diode current Id flowing in the diode D by the ratio of the number of the FETs 1 and the number of the FETs 2.

The diode D has temperature characteristics in which a forward voltage decreases as the temperature increases. In the present disclosure, based on the temperature characteristics of the diode D and the resistor R, the variable current Ip supplied from the PTAT current source 26 to the variable current source 23 (current mirror circuit) increases as the temperature increases.

The configuration example of the PTAT current source illustrated in FIG. 5 is an example and the PTAT current source is not necessarily configured as illustrated in FIG. 5. The first control circuit 20 in the embodiment may have a configuration that includes a PTAT current source configured in a manner different from that illustrated in FIG. 5.

An FET A and FETs B of the variable current source 23 (current mirror circuit) are NMOSFETs that have a substantially equivalent performance. The variable current source 23 (current mirror circuit) generates a variable current Iv, which is obtained by multiplying the variable current Ip supplied from the PTAT current source 26 by the ratio of the number of the FETs A and the number of the FETs B. In other words, the variable current Iv increases, in proportion to the variable current Ip supplied from the PTAT current source 26, as the temperature increases.

The second FET 21 has an ON resistance Ron2 (˜ Ron1) that is substantially equal to that of the first FET 12 of the input/output circuit 10 at the time when the same gate bias voltage is applied. Specifically, the first FET 12 and the second FET 21 are, for example, NMOSFETs of the same type. NMOSFETs of the same type represent NMOSFETs made of the same material or made by the same process. NMOSFETs of the same type may have the same device parameters such as the same gate length Lg or the same gate width Wg as well as made of the same material or made by the same process.

The second FET 21 is connected between the variable potential point VA and a reference potential point GND. A fixed potential that is the same potential as that at the reference potential point GND to which the first FET 12 is connected or a fixed potential that is different from that at the reference potential point GND to which the first FET 12 is connected may be supplied to the reference potential point GND to which the second FET 21 is connected. A gate of the first FET 12 of the input/output circuit 10 and a gate of the second FET 21 are electrically connected with a resistor RF interposed therebetween. The resistor RF has a high resistance of, for example, about 100 kΩ and has a function for suppressing leakage of a high frequency signal from the input/output circuit 10 to the first control circuit 20.

Furthermore, an output terminal of the operational amplifier circuit 24 is connected to the gate of the second FET 21. A non-inverted input terminal of the operational amplifier circuit 24 is connected to the variable potential point VA, and the potential of the variable potential point VA is fed back to the non-inverted input terminal of the operational amplifier circuit 24.

An inverted input terminal of the operational amplifier circuit 24 is connected to a fixed potential point FV illustrated in FIGS. 3 and 4. A potential VREF is applied from the constant voltage source 25 to the fixed potential point FV.

An operation with the configuration in Embodiment 1 described above will be described below.

In the configuration in Embodiment 1 illustrated in FIGS. 3 and 4, a feedback potential VFB to the non-inverted input terminal of the operational amplifier circuit 24 at the potential of the variable potential point VA is expressed by Equation (1).

$$VFB = ( Ic - Iv ) * Ron 2 \qquad ( 1 )$$

The operational amplifier circuit 24 operates in such a manner that the feedback potential VFB to the non-inverted input terminal and the potential VREF of the inverted input terminal are substantially the same. Thus, Equation (2) is satisfied.

$$VREF = ( Ic - Iv ) * Ron 2 \qquad ( 2 )$$

Equation (2) can be transformed into Equation (3).

$$Ron 2 = VREF / ( Ic - Iv ) \qquad ( 3 )$$

In Equation (3), (Ic-Iv) represents a current flowing in the second FET 21. The current (Ic-Iv) decreases as the variable current Iv increases, and also increases as the variable current Iv decreases. As described above, the variable current Iv increases, in proportion to the variable current Ip supplied from the PTAT current source 26, as the temperature increases. Therefore, the current (Ic-Iv) flowing in the second FET 21 decreases as the temperature increases.

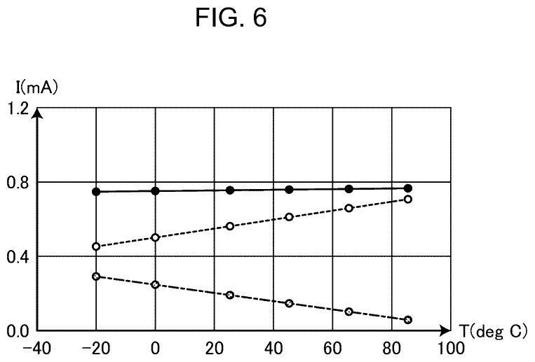

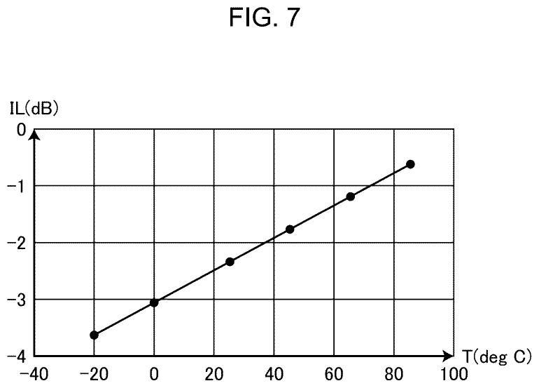

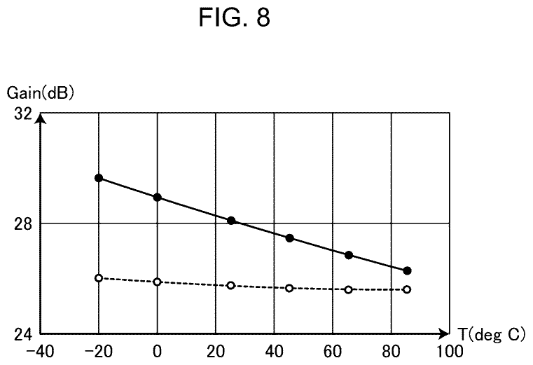

FIG. 6 is a diagram illustrating a temperature characteristics example of each current in the first control circuit. FIG. 7 is a diagram illustrating a temperature characteristics example of insertion loss in the input/output circuit. FIG. 8 is a illustrating diagram a temperature characteristics example of input/output gain in the power amplifier circuit. In FIGS. 6, 7, and 8, the horizontal axis represents temperature in Celsius.

The vertical axis in FIG. 6 represents a current value of each current in the first control circuit 20. A solid line illustrated in FIG. 6 represents the constant current Ic, and a broken line illustrated in FIG. 6 represents the variable current Iv. Furthermore, a dash-dotted line illustrated in FIG. 6 represents the current (Ic-Iv) flowing in the second FET 21.

The vertical axis in FIG. 7 represents the insertion loss IL of the input/output circuit 10.

The vertical axis in FIG. 8 represents the total gain of the power amplifier circuit 100. A solid line illustrated in FIG. 8 represents gain in the case where gain compensation by the attenuator circuit 1 according to the present disclosure is not implemented, and a broken line illustrated in FIG. 8 represents gain in the case where gain compensation by the attenuator circuit 1 according to the present disclosure is implemented.

In the characteristics represented by the solid line in FIG. 8, the gain decreases as the temperature increases. It is assumed that this decrease in the gain is caused by the temperature characteristics of a power amplifier element used in the power amplifier 2.

In the present disclosure, the constant current Ic, the variable current Iv, and the potential VREF are set based on the temperature characteristics of the power amplifier element used in the power amplifier 2. Specifically, for example, the current (Ic-Iv) flowing in the second FET 21 is set based on the characteristics represented by the broken line in FIG. 8 as a target value.

In Embodiment 1, the potential VREF applied to the inverted input terminal of the operational amplifier circuit 24 is a fixed potential. Therefore, the ON resistance Ron2 of the second FET 21 has characteristics of increasing as the temperature increases. The first control circuit 20 supplies a gate voltage of the second FET 21, as a gate bias voltage GBV of the first FET 12 of the input/output circuit 10, to the input/output circuit 10. As a result, the ON resistance Ron1 of the first FET 12 of the input/output circuit 10 varies in a manner similar to that in which the ON resistance Ron2 of the second FET 21 varies, and the insertion loss IL of the input/output circuit 10 has characteristics of decreasing as the temperature increases, as illustrated in FIG. 7. Thus, variations in the gain of the power amplifier 2 caused by the temperature characteristics of the power amplifier element can be canceled out, and variations in the total gain of the power amplifier circuit 100 can also be suppressed. Specifically, as indicated by the broken line in FIG. 8, the power amplifier circuit 100 that has a substantially constant total gain independent of a change in the temperature can be attained.

### Embodiment 2

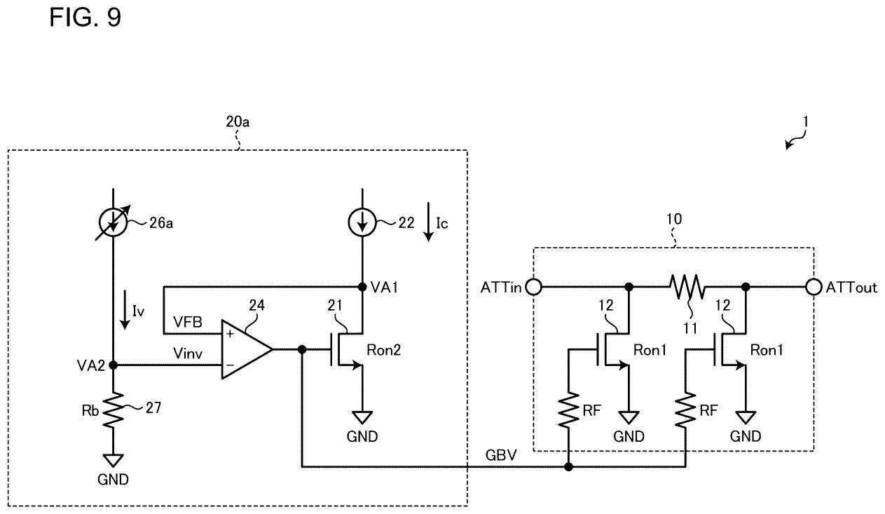

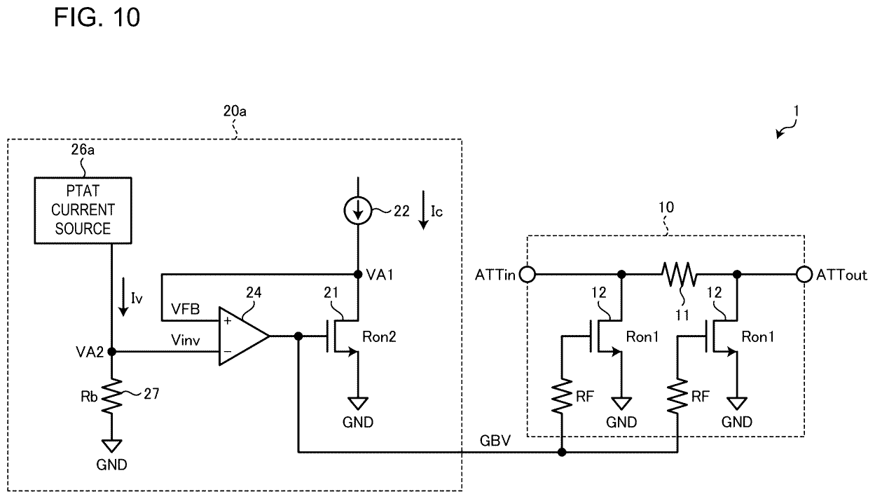

FIG. 9 is a block diagram illustrating a configuration example of a first control circuit in Embodiment 2. FIG. 10 is a block diagram illustrating a configuration example of a variable current source 4 the first control circuit in Embodiment 2. Features different from those in Embodiment 1 will be described in detail, and description of the same features as those in Embodiment 1 may be omitted.

In the configuration example in Embodiment 2, a first control circuit 20a includes the second FET 21, the constant current source 22, the operational amplifier circuit 24, a second variable current source 26a, and a second resistor 27.

The constant current source 22 supplies the constant current Ic to a first variable potential point VA1 illustrated in FIGS. 9 and 10.

As illustrated in 10, in the configuration in Embodiment 2, the second variable current source 26a is a PTAT current source. The second variable current source 26a (PTAT current source) generates the variable current Iv that increases as the temperature increases.

The output terminal of the operational amplifier circuit 24 is connected to the gate of the second FET 21. The non-inverted input terminal of the operational amplifier circuit 24 is connected to the first variable potential point VA1, and the potential of the first variable potential point VA1 is fed back to the non-inverted input terminal of the operational amplifier circuit 24.

In Embodiment 2, the inverted input terminal of the operational amplifier circuit 24 is connected to a second variable potential point VA2 illustrated in FIGS. 9 and 10. The second resistor 27 is connected between the second variable potential point VA2 and a reference potential point GND.

An operation with the configuration in Embodiment 2 described above will be described below.

In the configuration in Embodiment 2 illustrated in FIGS. 9 and 10, the feedback potential VFB to the non-inverted input terminal of the operational amplifier circuit 24 at the potential of the first variable potential point VA1 is expressed by Equation (4).

$$VFB = Ic \times Ron 2 \qquad ( 4 )$$

The potential of the second variable potential point VA2 is determined based on the variable current Iv supplied from the second variable current source 26a (PTAT current source). A potential Vinv of the inverted input terminal of the operational amplifier circuit 24 at the potential of the second variable potential point VA2 is expressed by Equation (5), where the resistance value of the second resistor 27 is represented by Rb.

$$Vinv = Iv \times Rb \qquad ( 5 )$$

The operational amplifier circuit 24 operates in such a manner that the feedback potential VFB to the non-inverted input terminal and the potential Vinv of the inverted input terminal are substantially the same. Thus, Equation (6) is satisfied.

$$Iv \times Rb = Ic \times Ron 2 \qquad ( 6 )$$

Equation (6) can be transformed into Equation (7).

$$Ron 2 = ( Iv / Ic ) \times Rb \qquad ( 7 )$$

Compared to the constant current Ic flowing in the second FET 21, the variable current Iv flowing in the second resistor 27 increases as the temperature increases. Therefore, (Iv/Ic) in Equation (7) increases as the temperature increases.

In Embodiment 2, the second resistor 27 is a fixed resistor. Therefore, the ON resistance Ron2 of the second FET 21 has characteristics of increasing as the temperature increases. The first control circuit 20a supplies the gate voltage of the second FET 21, as the gate bias voltage GBV of the first FET 12 of the input/output circuit 10, to the input/output circuit 10. As a result, the ON resistance Ron1 of the first FET 12 of the input/output circuit 10 varies in a manner similar to that in which the ON resistance Ron2 of the second FET 21 varies, and the insertion loss the input/output IL of circuit 10 has characteristics of decreasing as the temperature increases, as illustrated in FIG. 7. Thus, variations in the gain of the power amplifier 2 caused by the temperature characteristics of the power amplifier element can be canceled out, and variations in the total gain of the power amplifier circuit 100 can also be suppressed.

### Embodiment 3

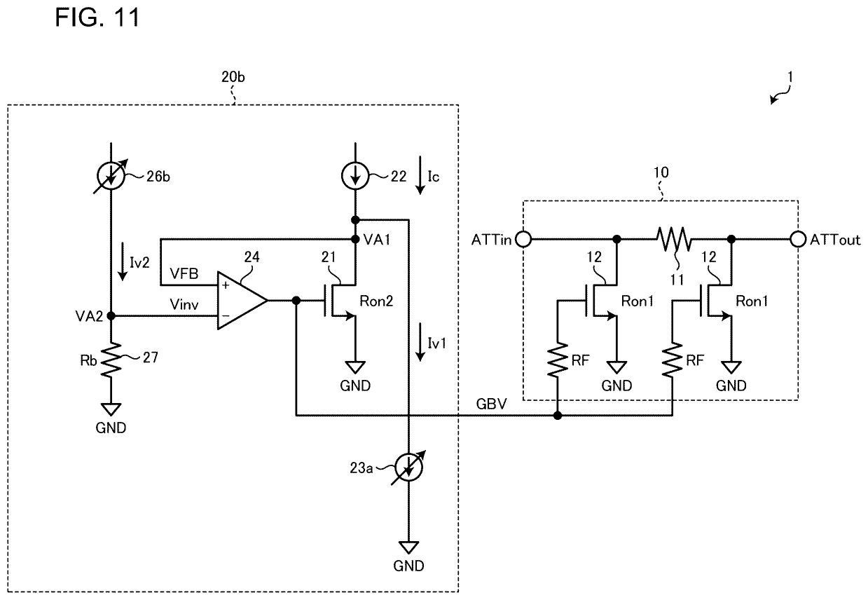

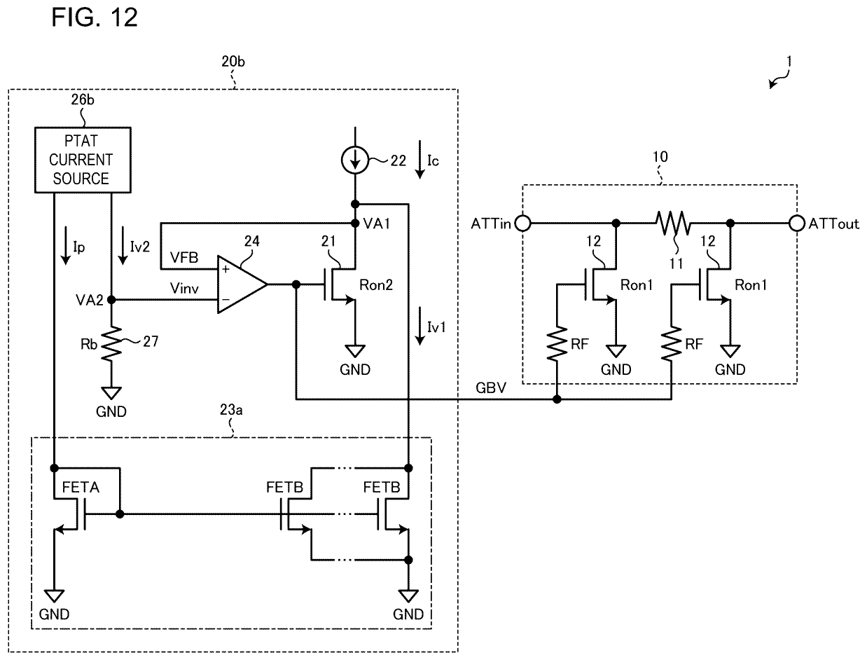

FIG. 11 is a block diagram illustrating a configuration example of a first control circuit in Embodiment 3. FIG. 12 is a block diagram illustrating a configuration example of a variable current source of the first control circuit in Embodiment 3. Features different from those in Embodiment 1 or Embodiment 2 will be described in detail, and description of the same features as those in Embodiment 1 or Embodiment 2 may be omitted.

In the configuration example in Embodiment 3, a first control circuit 20b includes the second FET 21, the constant current source 22, a first variable current source 23a, the operational amplifier circuit 24, a second variable current source 26b, and the second resistor 27.

The constant current source 22 supplies the constant current Ic to a first variable potential point VA1 illustrated in FIGS. 11 and 12. The first variable current source 23a is connected between the first variable potential point VA1 and the reference potential point GND. A fixed potential that is the same potential as that at the reference potential point GND to which the first FET 12 is connected and at the reference potential point GND to which the second FET 21 is connected or a fixed potential that is different from that at the reference potential point GND to which the first FET 12 is connected and at the reference potential point GND to which the second FET 21 is connected may be supplied to the reference potential point GND to which the first variable current source 23a is connected. The second variable current source 26b supplies a second variable current Iv2 to a second variable potential point VA2 illustrated in FIGS. 11 and 12.

In the configuration example illustrated in FIG. 12, the first variable current source 23a is a current mirror circuit. Furthermore, in the configuration example illustrated in FIG. 12, the second variable current source 26b is a PTAT current source. The second variable current source 26b (PTAT current source) generates a variable current that increases as the temperature increases. More specifically, the second variable current source 26b (PTAT current source) supplies the variable current Ip to the first variable current source 23a (current mirror circuit) and supplies the second variable current Iv2 to the second variable potential point VA2.

The FET A and the FETs B of the first variable current source 23a (current mirror circuit) are NMOSFETs that have a substantially equivalent performance. The first variable current source 23a (current mirror circuit) generates a first variable current Iv1, which is obtained by multiplying the variable current Ip supplied from the second variable current source 26b (PTAT current source) by the ratio of the number of the FETs A and the number of the FETs B. In other words, the first variable current Iv1 increases, in proportion to the variable current Ip supplied from the second variable current source 26b (PTAT current source), as the temperature increases.

The output terminal of the operational amplifier circuit 24 is connected to the gate of the second FET 21. The non-inverted input terminal of the operational amplifier circuit 24 is connected to the first variable potential point VA1, and the potential of the first variable potential point VA1 is fed back to the non-inverted input terminal of the operational amplifier circuit 24.

The inverted input terminal of the operational amplifier circuit 24 is connected to the second variable potential point VA2 illustrated in FIGS. 11 and 12, as in Embodiment 2. The second resistor 27 is connected between the second variable potential point VA2 and the reference potential point GND. A fixed potential that is the same potential as that at the reference potential point GND to which the first FET 12 is connected, at the reference potential point GND to which the second FET 21 is connected, and at the reference potential point GND to which the first variable current source 23a is connected or a fixed potential that is different from that at the reference potential point GND to which the first FET 12 is connected, at the reference potential point GND to which the second FET 21 is connected, and at the reference potential point GND to which the first variable current source 23a is connected may be supplied to the reference potential point GND to which the second resistor 27 is connected.

An operation with the configuration in Embodiment 3 described above will be described below.

In the configuration in Embodiment 3 illustrated in FIGS. 11 and 12, the feedback potential VFB to the non-inverted input terminal of the operational amplifier circuit 24 at the potential of the first variable potential point VA1 is expressed by Equation (8).

$$VFB = ( Ic - Iv 1 ) \times Ron 2 \qquad ( 8 )$$

As in Embodiment 2, the potential of the second variable potential point VA2 is determined based on the second variable current Iv2 supplied from the second variable current source 26b (PTAT current source). The potential Vinv of the inverted input terminal of the operational amplifier circuit 24 at the potential of the second variable potential point VA2 is expressed by Equation (9), where the resistance value of the second resistor 27 is represented by Rb.

$$Vinv = Iv 2 \times Rb \qquad ( 9 )$$

The operational amplifier circuit 24 operates in such a manner that the feedback potential VFB to the non-inverted input terminal and the potential VREF of the inverted input terminal are substantially the same. Thus, Equation (10) is satisfied.

$$Iv 2 \times Rb = ( Ic - Iv 1 ) \times Ron 2 \qquad ( 10 )$$

Equation (10) can be transformed into Equation (11).

$$Ron 2 = \{ Iv 2 / ( Ic - Iv 1 ) \} \times Rb \qquad ( 11 )$$

In Equation (11), (Ic-Iv1) represents a current flowing in the second FET 21. The current (Ic-Iv1) decreases as the first variable current Iv1 increases, and also increases as the first variable current Iv1 decreases. The first variable current Iv1 increases, in proportion to the variable current Ip supplied from the second variable current source 26b (PTAT current source), as the temperature increases. Therefore, the current (Ic-Iv1) flowing in the second FET 21 decreases as the temperature increases. In contrast, the second variable current Iv2 flowing in the second resistor 27 increases as the temperature increases.

In Embodiment 3, the second resistor 27 is a fixed resistor, as in Embodiment 2. As described above, in Equation (11), the current (Ic-Iv1) flowing in the second FET 21 decreases as the temperature increases, and the second variable current Iv2 increases as the temperature increases. Thus, the range in which the ON resistance Ron2 of the second FET 21 is able to be varied as a result of an increase in the temperature can be expanded compared to Embodiment 1 and Embodiment 2.

The first control circuit 20b supplies the gate voltage of the second FET 21, as the gate bias voltage GBV of the first FET 12 of the input/output circuit 10, to the input/output circuit 10. As a result, the ON resistance Ron1 of the first FET 12 of the input/output circuit 10 varies in a manner similar to that in which the ON resistance Ron2 of the second FET 21 varies, and the insertion loss IL of the input/output circuit 10 has characteristics of decreasing as the temperature increases, as illustrated in FIG. 7. Thus, variations in the gain of the power amplifier 2 caused by the temperature characteristics of the power amplifier element can be canceled out, and the power amplifier circuit 100 that has a substantially constant total gain independent of a change in the temperature can be attained, as indicated by the broken line in FIG. 8. Furthermore, the first control circuit 20b includes both the first variable current source 23a (corresponding to the variable current source 23 of the first control circuit 20) and the second variable current source 26b (corresponding to the second variable current source 26a of the first control circuit 20a). Thus, compared to the case where the first control circuit 20 is provided or the case where the first control circuit 20a is provided, the power amplifier circuit 100 that has a substantially constant total gain independent of a change in the temperature can be attained even in the case where a variation in the gain of the power amplifier circuit with respect to temperature is large.

As described above, with the attenuator circuit 1 according to each embodiment, the insertion loss IL of the input/output circuit 10 can be adjusted based on temperature. Specifically, the insertion loss IL of the input/output circuit 10 is caused to decrease as the temperature increases. Thus, variations in the gain of the power amplifier 2 caused by the temperature characteristics of the power amplifier element can be compensated for.

### Embodiment 4

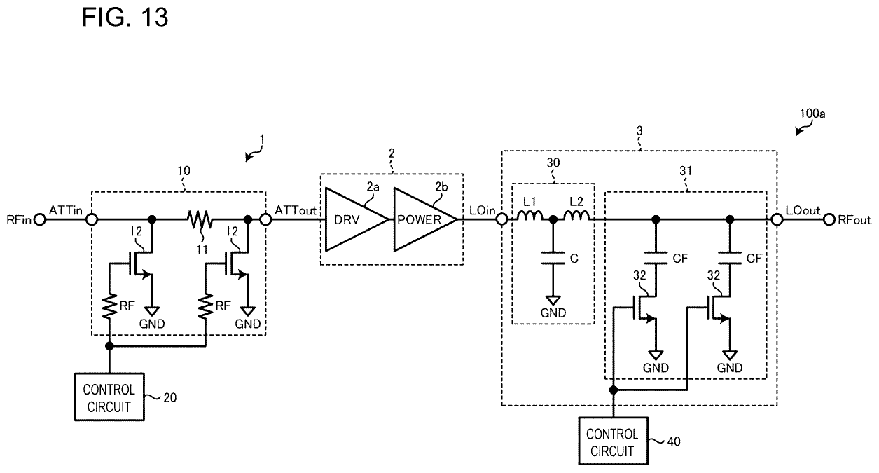

FIG. 13 is a diagram illustrating an example of a schematic configuration of a power amplifier circuit representing an application example of an output load circuit according to an embodiment. In the example illustrated in FIG. 13, a power amplifier circuit 100a includes the power amplifier 2 with a two-stage configuration including the drive-stage amplifier 2a and the power-stage amplifier 2b, as in FIG. 1. An output load circuit 3 is provided at a stage subsequent to the power amplifier 2.

In the example illustrated in FIG. 13, the output load circuit 3 includes an output matching circuit 30 of a so-called T type in which the inductors L1 and L2 are connected in series and a capacitor C is shunt-connected between the connection point between the inductors L1 and L2 and a reference potential point GND. An impedance matching circuit 31 in which a capacitor CF and a third FET 32 are connected in series between an output of the output matching circuit 30 and a reference potential point GND is provided.

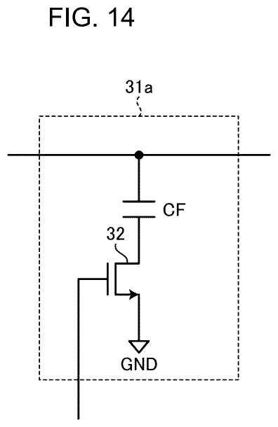

FIG. 14 is a block diagram illustrating a modification of the impedance matching circuit. In FIG. 13, the impedance matching circuit 31 with the configuration including two series circuits each including the capacitor CF and the third FET 32 is illustrated. However, as illustrated in FIG. 14, an impedance matching circuit 31a may have a configuration including one series circuit including the capacitor CF and the third FET 32.

In the configuration in Embodiment 4, a second control circuit 40 controls, based on temperature, the impedance of the output load circuit 3. Specifically, at a high temperature, by increasing the ON resistance of the third FET 32 of the impedance matching circuit 31 compared to that at a low temperature, the impedance of the output load circuit 3 including the output matching circuit 30 is increased. Thus, changes in the output characteristics of the power amplifier 2 as a result of an increase in the temperature of the power amplifier element can be compensated for.

More specifically, the output load circuit 3 includes the second control circuit 40 that controls a gate bias voltage for controlling the ON resistance of the third FET 32. In each of the embodiments described below, a specific configuration and operation of the second control circuit 40 will be described.

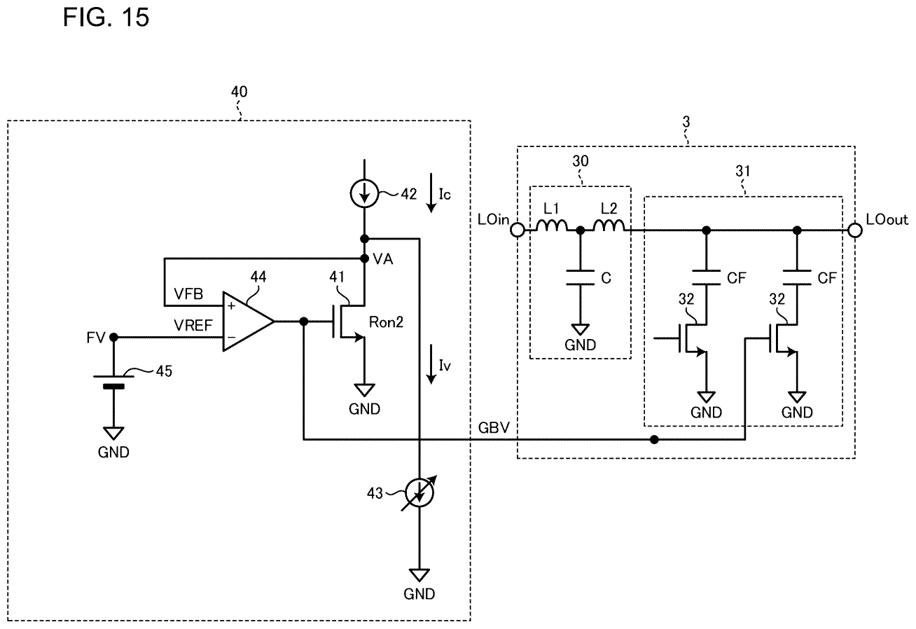

FIG. 15 is a block diagram illustrating a configuration example of the second control circuit in Embodiment 4. In the configuration example in Embodiment 4, the second control circuit 40 includes a fourth FET 41, a constant current source 42, a variable current source 43, an operational amplifier circuit 44, and a constant voltage source 45.

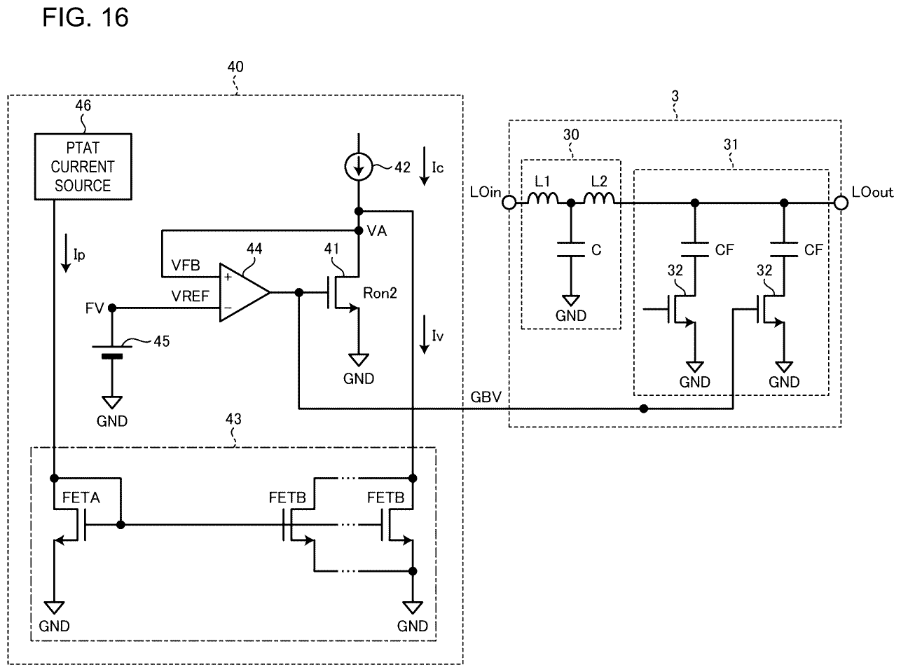

The constant current source 42 supplies the constant current Ic to a variable potential point VA illustrated in FIG. 15. The variable current source 43 is connected between the variable potential point VA and a reference potential point GND. FIG. 16 is a block diagram illustrating a configuration example of a variable current source of the second control circuit in Embodiment 4.

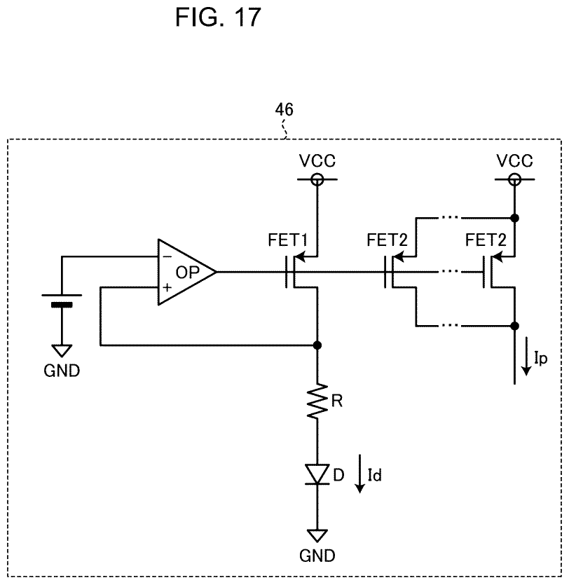

In the configuration example illustrated in FIG. 16, the variable current source 43 is a current mirror circuit. Furthermore, in the configuration example illustrated in FIG. 16, the second control circuit 40 includes a PTAT current source 46 that supplies the variable current Ip to an input of the variable current source 43 (current mirror circuit). FIG. 17 is a block diagram illustrating a configuration example of the PTAT current source.

The PTAT current source 46 is configured to generate a variable current that is proportional to the absolute temperature. In the configuration example illustrated in FIG. 17, the PTAT current source 46 is configured to generate the variable current Ip based on the temperature characteristics of the diode D.

In the example illustrated in FIG. 17, the FET 1 and the FETs 2 are PMOSFETS that have a substantially equivalent performance. The same voltage VCC is supplied to the FET 1 and the FETs 2. The PTAT current source 46 generates the variable current Ip, which is obtained by multiplying the diode current Id flowing in the diode D by the ratio of the number of the FETs 1 and the number of the FETs 2.

The diode D has temperature characteristics in which the forward voltage decreases as the temperature increases. In the present disclosure, based on the temperature characteristics of the diode D and the resistor R, the variable current Ip supplied from the PTAT current source 46 to the variable current source 43 (current mirror circuit) increases as the temperature increases.

The configuration example of the PTAT current source illustrated in FIG. 17 is an example and the PTAT current source is not necessarily configured as illustrated in FIG. 17. The second control circuit 40 in the embodiment may have a configuration that includes a PTAT current source configured in a manner different from that illustrated in FIG. 17.

The FET A and the FETs B of the variable current source 43 (current mirror circuit) are NMOSFETs that have a substantially equivalent performance. The variable current source 43 (current mirror circuit) generates the variable current Iv, which is obtained by multiplying the variable current Ip supplied from the PTAT current source 46 by the ratio of the number of the FETs A and the number of the FETs B. In other words, the variable current Iv increases, in proportion to the variable current Ip supplied from the PTAT current source 46, as the temperature increases.

The fourth FET 41 has the ON resistance Ron2 (˜ Ron1) that is substantially equal to that of the third FET 32 of the impedance matching circuit 31 at the time when the same gate bias voltage is applied. Specifically, the third FET 32 and the fourth FET 41 are, for example, NMOSFETs of the same type. NMOSFETs of the same type represent NMOSFETs made of the same material or made by the same process. NMOSFETs of the same type may have the same device parameters such as the same gate length Lg or the same gate width Wg as well as made of the same material or made by the same process.

The fourth FET 41 is connected between the variable potential point VA and a reference potential point GND. A fixed potential that is the same potential as that at the reference potential point GND to which the third FET 32 is connected or a fixed potential that is different from that at the reference potential point GND to which the third FET 32 is connected may be supplied to the reference potential point GND to which the fourth FET 41 is connected. A gate of the third FET 32 of the impedance matching circuit 31 and a gate of the fourth FET 41 are electrically connected with a resistor RF interposed therebetween. The resistor RF has a high resistance of, for example, about 100 kΩ and has a function for suppressing leakage of a high frequency signal from the impedance matching circuit 31 to the second control circuit 40.

An output terminal of the operational amplifier circuit 44 is connected to the gate of the fourth FET 41. A non-inverted input terminal of the operational amplifier circuit 44 is connected to the variable potential point VA, and the potential of the variable potential point VA is fed back to the non-inverted input terminal of the operational amplifier circuit 44.

An inverted input terminal of the operational amplifier circuit 44 is connected to a fixed potential point FV illustrated in FIGS. 15 and 16. The potential VREF is applied from the constant voltage source 45 to the fixed potential point FV.

An operation with the configuration in Embodiment 4 described above will be described below.

In the configuration in Embodiment 4 illustrated in FIGS. 15 and 16, the feedback potential VFB to the non-inverted input terminal of the operational amplifier circuit 44 at the potential of the variable potential point VA is expressed by Equation (12).

$$VFB = ( Ic = Iv ) \times Ron 2 \qquad ( 12 )$$

The operational amplifier circuit 44 operates in such a manner that the feedback potential VFB to the non-inverted input terminal and the potential VREF of the inverted input terminal are substantially the same. Thus, Equation (13) is satisfied.

$$VREF = ( Ic - Iv ) \times Ron 2 \qquad ( 13 )$$

Equation (13) can be transformed into Equation (14).

$$Ron 2 = VREF / ( Ic - Iv ) \qquad ( 14 )$$

In Equation (14), (Ic-Iv) represents a current flowing in the fourth FET 41. The current (Ic-Iv) decreases as the variable current Iv increases, and also increases as the variable current Iv decreases. As described above, the variable current Iv increases, in proportion to the variable current Ip supplied from the PTAT current source 46, as the temperature increases. Thus, the current (Ic-Iv) flowing in the fourth FET 41 decreases as the temperature increases.

In the present disclosure, the constant current Ic, the variable current Iv, and the potential VREF are set based on the temperature characteristics of the power amplifier element used in the power amplifier 2. Specifically, for example, the current (Ic-Iv) flowing in the fourth FET 41 is set based on characteristics, as a target value, that cancel out a degradation of value output characteristics as a result of an increase in the temperature.

In Embodiment 4, the potential VREF applied to the inverted input terminal of the operational amplifier circuit 44 is a fixed potential. Thus, the ON resistance Ron2 of the fourth FET 41 has characteristics of increasing as the temperature increases. The second control circuit 40 supplies a gate voltage of the fourth FET 41, as a gate bias voltage GBV of the third FET 32 of the impedance matching circuit 31, to the impedance matching circuit 31. As a result, the ON resistance Ron1 of the third FET 32 of the impedance matching circuit 31 varies in a manner similar to that in which the ON resistance Ron2 of the fourth FET 41 varies, the value of capacitor CF can be caused to decrease as the temperature increases by causing the third FET 32 to get closer to OFF as the temperature increases, and the impedance of the output load circuit 3 including the output matching circuit 30 has characteristics of increasing as the temperature increases. Thus, changes in the output characteristics of the power amplifier 2 (for example, the optimal load impedance, which is an impedance at which the maximum output power and the maximum efficiency can be achieved when an input signal with a predetermined input power and at a predetermined input frequency is supplied) as a result of an increase in the temperature of the power amplifier element can be compensated for. Specifically, a degradation of the output characteristics of the power amplifier circuit 100a as a result of an increase in the temperature can be suppressed.

### Embodiment 5

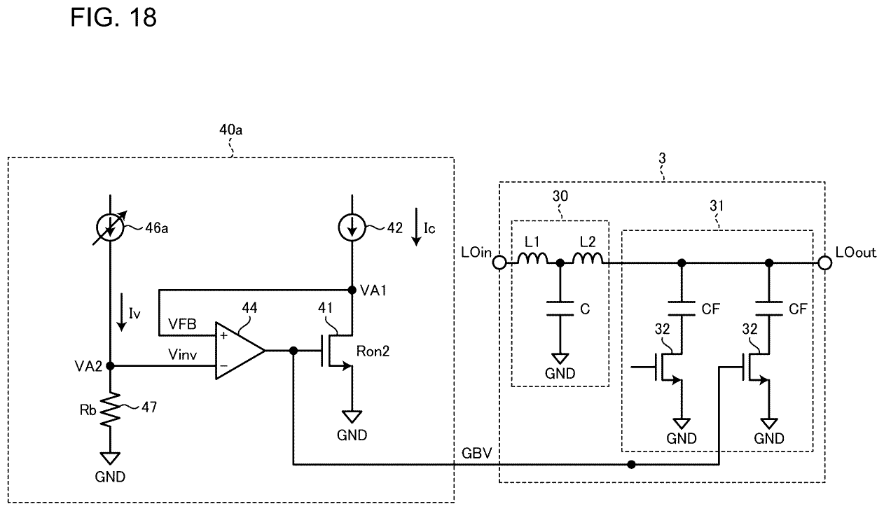

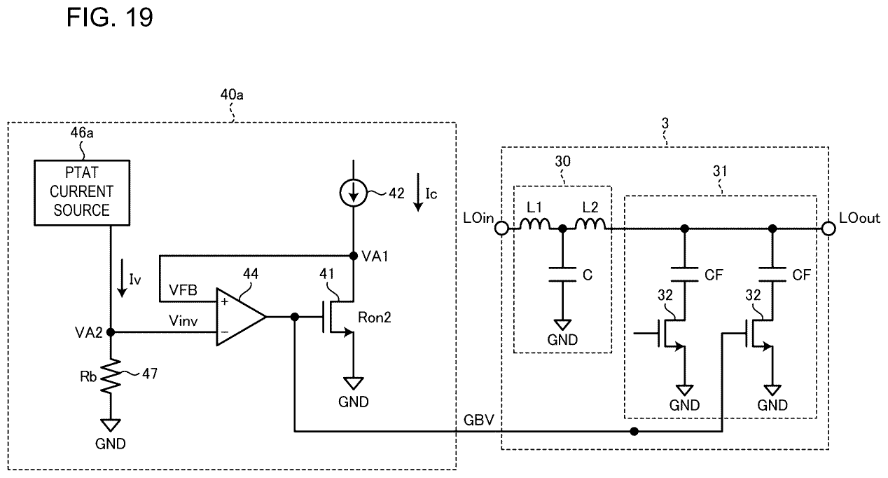

FIG. 18 is a block diagram illustrating a configuration example of a second control circuit in Embodiment 5. FIG. 19 is a block diagram illustrating a configuration example of a variable current source of the second control circuit in Embodiment 5. Features different from those in Embodiment 4 will be described in detail, and description of the same features as those in Embodiment 4 may be omitted.

In the configuration example in Embodiment 5, a second control circuit 40a includes the fourth FET 41, the constant current source 42, the operational amplifier circuit 44, a second variable current source 46a, and a second resistor 47.

The constant current source 42 supplies the constant current Ic to a first variable potential point VA1 illustrated in FIGS. 18 and 19.

As illustrated in FIG. 19, in the configuration in Embodiment 5, the second variable current source 46a is a PTAT current source. The second variable current source 46a (PTAT current source) generates the variable current Iv that increases as the temperature increases.

The output terminal of the operational amplifier circuit 44 is connected to the gate of the fourth FET 41. The non-inverted input terminal of the operational amplifier circuit 44 is connected to the first variable potential point VA1, and the potential of the first variable potential point VA1 is fed back to the non-inverted input terminal of the operational amplifier circuit 44.

In Embodiment 5, the inverted input terminal of the operational amplifier circuit 44 is connected to a second variable potential point VA2 illustrated in FIGS. 18 and 19. The second resistor 47 is connected between the second variable potential point VA2 and a reference potential point GND.

An operation with the configuration in Embodiment 5 described above will be described below.

In the configuration in Embodiment 5 illustrated in FIGS. 18 and 19, the feedback potential VFB to the non-inverted input terminal of the operational amplifier circuit 44 at the potential of the first variable potential point VA1 is expressed by Equation (15).

$$VFB = Ic \times Ron 2 \qquad ( 15 )$$

The potential of the second variable potential point VA2 is determined based on the variable current Iv supplied from the second variable current source 46a (PTAT current source). The potential Vinv of the inverted input terminal of the operational amplifier circuit 44 at the potential of the second variable potential point VA2 is expressed by Equation (16), where the resistance value of the second resistor 47 is represented by Rb.

$$Vinv = Iv \times Rb \qquad ( 16 )$$

The operational amplifier circuit 44 operates in such a manner that the feedback potential VFB to the non-inverted input terminal and the potential Vinv of the inverted input terminal are substantially the same. Thus, Equation (17) is satisfied.

$$Iv \times Rb = Ic \times Ron 2 \qquad ( 17 )$$

Equation (17) can be transformed into Equation (18).

$$Ron 2 = ( Iv \times Ic ) \times Rb \qquad ( 18 )$$

Compared to the constant current Ic flowing in the fourth FET 41, the variable current Iv flowing in the second resistor 47 increases as the temperature increases. Therefore, (Iv/Ic) in Equation (18) increases as the temperature increases.

In Embodiment 5, the second resistor 47 is a fixed resistor. Thus, the ON resistance Ron2 of the fourth FET 41 has characteristics of increasing as the temperature increases. The second control circuit 40a supplies the gate voltage of the fourth FET 41, as the gate bias voltage GBV of the third FET 32 of the impedance matching circuit 31, to the impedance matching circuit 31. As a result, the ON resistance Ron1 of the third FET 32 of the impedance matching circuit 31 varies in a manner similar to that in which the ON resistance Ron2 of the fourth FET 41 varies, the value of the capacitor CF can be caused to decrease as the temperature increases by causing the third FET 32 to get closer to OFF as the temperature increases, and the impedance of the impedance matching circuit 31 has characteristics of increasing as the temperature increases. Thus, changes in the output characteristics of the power amplifier 2 (for example, the optimal load impedance) as a result of an increase in the temperature of the power amplifier element can be compensated for, and a degradation of the output characteristics of the power amplifier circuit 100a can be suppressed.

### Embodiment 6

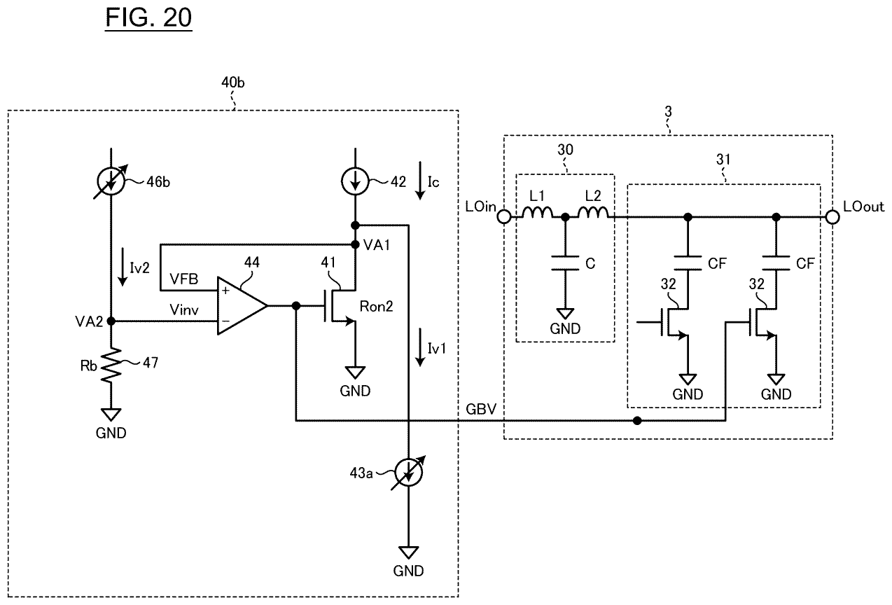

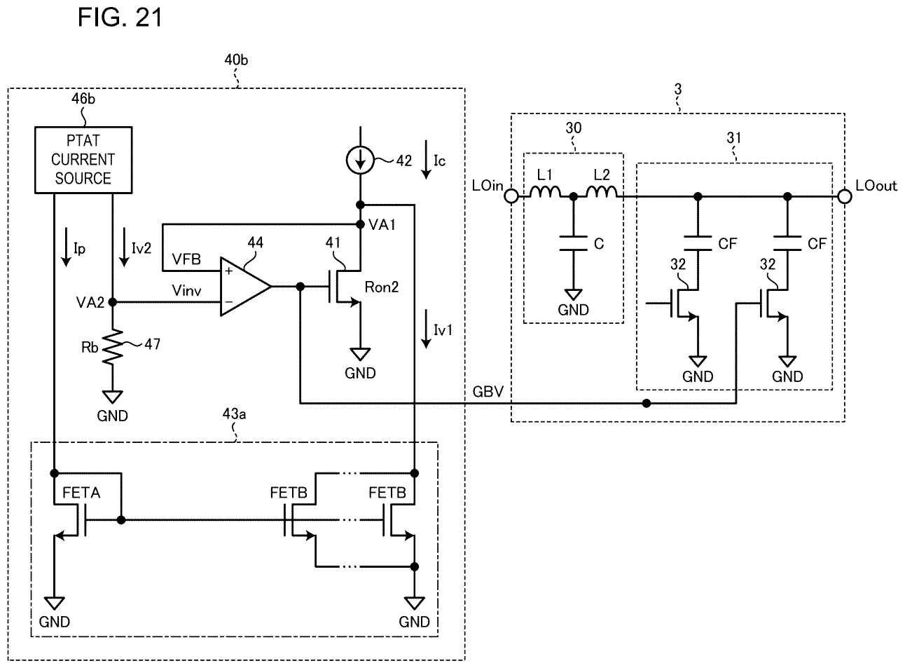

FIG. 20 is a block diagram illustrating a configuration example of a second control circuit in Embodiment 6. FIG. 21 is a block diagram illustrating a configuration example of a variable current source of the second control circuit in Embodiment 6. Features different from those in Embodiment 4 or Embodiment 5 will be described in detail, and description of the same features as those in Embodiment 4 or Embodiment 5 may be omitted.

In the configuration in Embodiment 6, the second control circuit 40 includes the fourth FET 41, the constant current source 42, a first variable current source 43a, the operational amplifier circuit 44, a second variable current source 46b, and the second resistor 47.

The constant current source 42 supplies the constant current Ic to a first variable potential point VA1 illustrated in FIGS. 20 and 21. The first variable current source 43a is connected between the first variable potential point VA1 and a reference potential point GND. A fixed potential that is the same potential as that at the reference potential point GND to which the third FET 32 is connected and at the reference potential point GND to which the fourth FET 41 is connected or a fixed potential that is different from that at the reference potential point GND to which the third FET 32 is connected and at the reference potential point GND to which the fourth FET 41 is connected may be supplied to the reference potential point GND to which the first variable current source 43a is connected. The second variable current source 46b supplies the second variable current Iv2 to a second variable potential point VA2 illustrated in FIGS. 20 and 21.

In the configuration example illustrated in FIG. 21, the first variable current source 43a is a current mirror circuit. Furthermore, in the configuration example illustrated in FIG. 21, the second variable current source 46b is a PTAT current source. The second variable current source 46b (PTAT current source) generates a variable current that increases as the temperature increases. More specifically, the second variable current source 46b (PTAT current source) supplies the variable current Ip to the first variable current source 43a (current mirror circuit) and supplies the second variable current Iv2 to the second variable potential point VA2.

The FET A and the FETs B of the first variable current source 43a (current mirror circuit) are NMOSFETs that have a substantially equivalent performance. The first variable current source 43a (current mirror circuit) generates the first variable current Iv1, which is obtained by multiplying the variable current Ip supplied from the second variable current source 46b (PTAT current source) by the ratio of the number of the FETs A and the number of the FETs B. In other words, the first variable current Iv1 increases, in proportion to the variable current Ip supplied from the second variable current source 46b (PTAT current source), as the temperature increases.

The output terminal of the operational amplifier circuit 44 is connected to the gate of the fourth FET 41. The non-inverted input terminal of the operational amplifier circuit 44 is connected to the first variable potential point VA1, and the potential of the first variable potential point VA1 is fed back to the non-inverted input terminal of the operational amplifier circuit 44.

As in Embodiment 5, the inverted input terminal of the operational amplifier circuit 44 is connected to the second variable potential point VA2 illustrated in FIGS. 20 and 21. The second resistor 47 is connected between the second variable potential point VA2 and the reference potential point GND. A fixed potential that is the same potential as that at the reference potential point GND to which the third FET 32 is connected, at the reference potential point GND to which the fourth FET 41 is connected, and at the reference potential point GND to which the first variable current source 43a is connected or a fixed potential that is different from that at the reference potential point GND to which the third FET 32 is connected, at the reference potential point GND to which the fourth FET 41 is connected, and at the reference potential point GND to which the first variable current source 43a is connected may be supplied to the reference potential point GND to which the second resistor 47 is connected.

An operation with the configuration in Embodiment 6 described above will be described below.

In the configuration in Embodiment 6 illustrated in FIGS. 20 and 21, the feedback potential VFB to the non-inverted input terminal of the operational amplifier circuit 44 at the potential of the first variable potential point VA1 is expressed by Equation (19).

$$VFB = ( Ic - Iv 1 ) \times Ron 2 \qquad ( 19 )$$

As in Embodiment 5, the potential of the second variable potential point VA2 is determined based on the second variable current Iv2 supplied from the second variable current source 46b (PTAT current source). The potential Vinv of the inverted input terminal of the operational amplifier circuit 44 at the potential of the second variable potential point VA2 is expressed by Equation (20), where the resistance value of the second resistor 47 is represented by Rb.

$$Vinv = Iv 2 \times Rb \qquad ( 20 )$$

The operational amplifier circuit 44 operates in such a manner that the feedback potential VFB to the non-inverted input terminal and the potential VREF of the inverted input terminal are substantially the same. Thus, Equation (21) is satisfied.

$$Iv 2 \times Rb = ( Ic - Iv 1 ) \times Ron 2 \qquad ( 21 )$$

Equation (21) can be transformed into Equation (22).

$$Ron 2 = \{ Iv 2 / ( Ic - Iv 1 ) \} \times Rb \qquad ( 22 )$$

In Equation (22), (Ic-Iv1) represents a current flowing in the fourth FET 41. The current (Ic-Iv1) decreases as the first variable current Iv1 increases, and also increases as the first variable current Iv1 decreases. The first variable current Iv1 increases, in proportion to the variable current Ip supplied from the second variable current source 46b (PTAT current source), as the temperature increases. Thus, the current (Ic-Iv1) flowing in the fourth FET 41 decreases as the temperature increases. In contrast, the second variable current Iv2 flowing in the second resistor 47 increases as the temperature increases.

In Embodiment 6, the second resistor 47 is a fixed resistor, as in Embodiment 5. As described above, in Equation (22), the current (Ic-Iv1) flowing in the fourth FET 41 decreases as the temperature increases, and the second variable current Iv2 increases as the temperature increases. Thus, the range in which the ON resistance Ron2 of the fourth FET 41 is able to be varied as a result of an increase in the temperature can be expanded compared to Embodiment 4 and Embodiment 5.

A second control circuit 40b supplies the gate voltage of the fourth FET 41, as the gate bias voltage GBV of the third FET 32 of the impedance matching circuit 31, to the impedance matching circuit 31. As a result, the ON resistance Ron1 of the third FET 32 of the impedance matching circuit 31 varies in a manner similar to that in which the ON resistance Ron2 of the fourth FET 41 varies, the value of the capacitor CF can be caused to decrease as the temperature increases by causing the third FET 32 to get closer to OFF as the temperature increases, and the impedance of the impedance matching circuit 31 has characteristics of increasing as the temperature increases. Thus, changes in the output characteristics of the power amplifier 2 (for example, the optimal load impedance) as a result of an increase in the temperature of the power amplifier element can be compensated for, and a degradation of the output characteristics of the power amplifier circuit 100a can be suppressed. Furthermore, the second control circuit 40b includes both the third variable current source 43a (corresponding to the variable current source 43 of the second control circuit 40) and the fourth variable current source 46b (corresponding to the second variable current source 46a of the second control circuit 40a). Thus, compared to the case where the second control circuit 40 is provided or the case where the second control circuit 40a is provided, a degradation of the output characteristics of the power amplifier circuit 100a can be suppressed even in the case where a change in the output characteristics of the power amplifier 2 as a result of an increase in the temperature of the power amplifier element is large.

As described above, with the attenuator circuit 1 according to each embodiment, the insertion loss IL of the input/output circuit 10 can be adjusted based on the temperature. Specifically, the insertion loss IL of the input/output circuit 10 can be caused to decrease as the temperature increases. Thus, variations in the gain of the power amplifier 2 caused by the temperature characteristics of the power amplifier element can be compensated for.

Furthermore, the impedance of the impedance matching circuit 31 can be adjusted based on the temperature. Specifically, the impedance of the impedance matching circuit 31 is caused to increase as the temperature increases. Thus, changes in the output characteristics of the power amplifier 2 as a result of an increase in the temperature of the power amplifier element can be compensated for.

Furthermore, with the output load circuit 3 according to each of the embodiments, the impedance of the impedance matching circuit 31 can be adjusted based on the temperature. Specifically, the impedance of the impedance matching circuit 31 is caused to increase as the temperature increases. Thus, a degradation of the output characteristics of the power amplifier circuit 100a can be suppressed.

The embodiments described above are intended to facilitate understanding of the present disclosure and are not to be interpreted as limiting the present invention. The present disclosure can be modified or improved without departing from the gist of the disclosure, and the present disclosure encompasses equivalents thereof.

The T present disclosure may include the following configurations as described above or instead of the above.

(1) An attenuator circuit according to an aspect of the present disclosure includes an input/output circuit that is provided at a stage preceding a power amplifier; and a first control circuit that controls a gain of the input/output circuit. The input/output circuit includes at least a first resistor that is connected between an input terminal and an output terminal, and a first FET that is connected between the output terminal and a reference potential point. The first control circuit includes at least a second FET that has an ON resistance that is substantially equal to an ON resistance of the first FET at a time when a gate bias voltage that is the same as a gate bias voltage of the first FET is applied. A gate of the first FET and a gate of the second FET are electrically connected.

With this configuration, by controlling the ON resistance of the second FET, the gate bias voltage of the first FET can be controlled. Thus, insertion loss of the power amplifier can be controlled, and variations in the gain of the power amplifier caused by temperature characteristics of a power amplifier element can be canceled out.

(2) In the attenuator circuit according to (1), the second FET is connected between a variable potential point and a reference potential point. The first control circuit includes a constant current source that supplies a constant current to the variable potential point, a variable current source that is connected between the variable potential point and a reference potential point, an operational amplifier circuit whose output terminal is connected to the gate of the second FET, whose non-inverted input terminal is connected to the variable potential point, and whose inverted input terminal is connected to a fixed potential point, and a constant voltage source that applies a constant voltage to the fixed potential point.

With this configuration, by controlling the current flowing in the second FET, the ON resistance of the second FET can be controlled. Specifically, by increasing the current of the variable current source, the ON resistance of the second FET increases. Thus, the insertion loss of the power amplifier can be controlled.

(3) In the attenuator circuit according to (2), the variable current source includes a current mirror circuit. The first control circuit further includes a PTAT current source that supplies a variable current to an input of the current mirror circuit.

With this configuration, the variable current that is proportional to absolute temperature can be generated. Thus, under a high temperature environment, the insertion loss of the power amplifier can be reduced.

(4) In the attenuator circuit according to (1), the second FET is connected between a first variable potential point and a reference potential point. The first control circuit includes a constant current source that supplies a constant current to the first variable potential point, an operational amplifier circuit whose output terminal is connected to the gate of the second FET, whose non-inverted input terminal is connected to the first variable potential point, and whose inverted input terminal is connected to a second variable potential point that is different from the first variable potential point, a second resistor that is connected between the second variable potential point and a reference potential point, and a variable current source that supplies a variable current to the second variable potential point.

With this configuration, by controlling the current flowing in the second resistor, the ON resistance of the second FET can be controlled. Specifically, by increasing the current of the variable current source, the ON resistance of the second FET increases. Thus, the insertion loss of the power amplifier can be controlled.

(5) In the attenuator circuit according to (4), the variable current source is a PTAT current source.

With this configuration, the variable current that is proportional to the absolute temperature can be generated. Thus, under a high temperature environment, the insertion loss of the power amplifier can be reduced.

(6) In the attenuator circuit according to (1), the second FET is connected between a first variable potential point and a reference potential point, the first control circuit includes a constant current source that supplies a constant current to the first variable potential point, a first variable current source that is connected between the first variable potential point and a reference potential point, an operational amplifier circuit whose output terminal is connected to the gate of the second FET, whose non-inverted input terminal is connected to the first variable potential point, and whose inverted input terminal is connected to a second variable potential point that is different from the first variable potential point, a second resistor that is connected between the second variable potential point and a reference potential point, and a second variable current source that supplies a second variable current to the second variable potential point.

With this configuration, by controlling at least one of the current flowing in the second FET and the current flowing in the second resistor, the ON resistance of the second FET can be controlled. Specifically, by increasing at least one of the current of the first variable current source and the current of the second variable current source, the ON resistance of the second FET increases. Thus, the insertion loss of the power amplifier can be controlled.

(7) In the attenuator circuit according to (6), the first variable current source includes a current mirror circuit, and the second variable current source is a PTAT current source and supplies a variable current to an input of the current mirror circuit.

With this configuration, a second variable current that is proportional to the absolute temperature can be generated. Furthermore, a first variable current that is proportional to the variable current generated by the PTAT current source can be generated. Thus, under a high temperature environment, the insertion loss of the power amplifier can be reduced.

(8) The attenuator circuit according to (1) further includes an output matching circuit that is provided at a stage subsequent to the power amplifier, a capacitor and a third FET that are connected in series between an output of the output matching circuit and a reference potential point, and a second control circuit that controls an impedance of the output matching circuit. The second control circuit includes at least a fourth FET that has an ON resistance that is substantially equal to an ON resistance of the third FET at a time when a gate bias voltage that is the same as a gate bias voltage of the third FET is applied. A gate of the third FET and a gate of the fourth FET are electrically connected.

With this configuration, by controlling the ON resistance of the fourth FET, the gate bias voltage of the third FET can be controlled. Thus, the impedance of an output load circuit including the output matching circuit can be controlled, and the impedance of the output load circuit including the output matching circuit can be optimized based on the temperature characteristics of the power amplifier element.

(9) In the attenuator circuit according to (8), the fourth FET is connected between a variable potential point and a reference potential point, and the second control circuit includes a constant current source that supplies a constant current to the variable potential point, a variable current source that is connected between the variable potential point and a reference potential point, an operational amplifier circuit whose output terminal is connected to the gate of the fourth FET, whose non-inverted input terminal is connected to the variable potential point, and whose inverted input terminal is connected to a fixed potential point, and a constant voltage source that applies a constant voltage to the fixed potential point.

With this configuration, by controlling the current flowing in the fourth FET, the ON resistance of the fourth FET can be controlled. Specifically, by increasing the current of the variable current source, the ON resistance of the fourth FET increases, and the impedance of the output load circuit including the output matching circuit can be increased. Thus, changes in the output characteristics of the power amplifier as a result of an increase in the temperature of the power amplifier element can be compensated for, and a degradation of the output characteristics of the power amplifier circuit can be suppressed.

In the attenuator circuit according to (9), the variable current source includes a current mirror circuit, and the second control circuit further includes a PTAT current source that supplies a variable current to an input of the current mirror circuit.

With this configuration, the variable current that is proportional to the absolute temperature can be generated. Thus, under a high temperature environment, the impedance of the output load circuit including the output matching circuit can be increased.

(11) In the attenuator circuit according to (8), the fourth FET is connected between a first variable potential point and a reference potential point, and the second control circuit includes a constant current source that supplies a constant current to the first variable potential point, an operational amplifier circuit whose output terminal is connected to the gate of the fourth FET, whose non-inverted input terminal is connected to the first variable potential point, and whose inverted input terminal is connected to a second variable potential point that is different from the first variable potential point, a resistor that is connected between the second variable potential point and a reference potential point, and a variable current source that supplies a variable current to the second variable potential point.

With this configuration, by controlling the current flowing in the resistor, the ON resistance of the fourth FET can be controlled. Specifically, by increasing the current of the variable current source, the ON resistance of the fourth FET increases, and the impedance of the output load circuit including the output matching circuit can be increased. Thus, changes in the output characteristics of the power amplifier as a result of an increase in the temperature of the power amplifier element can be compensated for, and a degradation of the output characteristics of the power amplifier circuit can be suppressed.

(12) In the attenuator circuit according to (11), the variable current source is a PTAT current source.

With this configuration, the variable current that is proportional to the absolute temperature can be generated. Thus, under a high temperature environment, the impedance of the output load circuit including the output matching circuit can be increased.

(13) In the attenuator circuit according to (8), the fourth FET is connected between a first variable potential point and a reference potential point. The second control circuit includes a constant current source that supplies a constant current to the first variable potential point, a first variable current source that is connected between the first variable potential point and a reference potential point, an operational amplifier circuit whose output terminal is connected to the gate of the fourth FET, whose non-inverted input terminal is connected to the first variable potential point, and whose inverted input terminal is connected to a second variable potential point that is different from the first variable potential point, a resistor that is connected between the second variable potential point and a reference potential point, and a second variable current source that supplies a second variable current to the second variable potential point.

With this configuration, by controlling at least one of the current flowing in the fourth FET and the current flowing in the resistor, the ON resistance of the fourth FET can be controlled. Specifically, by increasing at least one of the current of the first variable current source and the current of the second variable current source, the ON resistance of the fourth FET increases, and the impedance of the output load circuit including the output matching circuit can be increased. Thus, changes in the output characteristics of the power amplifier as a result of an increase in the temperature of the power amplifier element can be compensated for, and a degradation of the output characteristics of the power amplifier circuit can be suppressed.

(14) In the attenuator circuit according to (13), the first variable current source includes a current mirror circuit, and the second variable current source is a PTAT current source and supplies a variable current to an input of the current mirror circuit.

With this configuration, a second variable current that is proportional to the absolute temperature can be generated. Furthermore, a first variable current that is proportional to the variable current generated by the PTAT current source can be generated. Thus, under a high temperature environment, the impedance of the output load circuit including the output matching circuit can be increased.

(15) An output load circuit according to an aspect of the present disclosure includes an output matching circuit that is provided at a stage subsequent to a power amplifier, a capacitor and a third FET that are connected in series between an output of the output matching circuit and a reference potential point, and a second control circuit that controls an impedance of the output matching circuit. The second control circuit includes at least a fourth FET that has an ON resistance that is substantially equal to an ON resistance of the third FET at a time when a gate bias voltage that is the same as a gate bias voltage of the third FET is applied. A gate of the third FET and a gate of the fourth FET are electrically connected.

With this configuration, by controlling the ON resistance of the fourth FET, the gate bias voltage of the third FET can be controlled. Thus, the impedance of the output load circuit can be controlled, and the impedance of the output load circuit can be optimized based on the temperature characteristics of the power amplifier element.

(16) In the output load circuit according to (15), the fourth FET is connected between a variable potential point and a reference potential point, and the second control circuit includes a constant current source that supplies a constant current to the variable potential point, a variable current source that is connected between the variable potential point and a reference potential point, an operational amplifier circuit whose output terminal is connected to the gate of the fourth FET, whose non-inverted input terminal is connected to the variable potential point, and whose inverted input terminal is connected to a fixed potential point, and a constant voltage source that applies a constant voltage to the fixed potential point.

With this configuration, by controlling the current flowing in the fourth FET, the ON resistance of the fourth FET can be controlled. Specifically, by increasing the current of the variable current source, the ON resistance of the fourth FET increases, and the impedance of the output load circuit can be increased. Thus, changes in the output characteristics of the power amplifier as a result of an increase in the temperature of the power amplifier element can be compensated for, and a degradation of the output characteristics of the power amplifier circuit can be suppressed.

(17) In the output load circuit according to (16), the variable current source includes a current mirror circuit, and the second control circuit further includes a PTAT current source that supplies a variable current to an input of the current mirror circuit.

With this configuration, the variable current that is proportional to the absolute temperature can be generated. Thus, under a high temperature environment, the impedance of the output load circuit can be increased.

(18) In the output load circuit according to (15), the fourth FET is connected between a first variable potential point and a reference potential point, and the second control circuit includes a constant current source that supplies a constant current to the first variable potential point, an operational amplifier circuit whose output terminal is connected to the gate of the fourth FET, whose non-inverted input terminal is connected to the first variable potential point, and whose inverted input terminal is connected to a second variable potential point that is different from the first variable potential point, a resistor that is connected between the second variable potential point and a reference potential point, and a variable current source that supplies a variable current to the second variable potential point.

With this configuration, by controlling the current flowing in the resistor, the ON resistance of the fourth FET can be controlled. Specifically, by increasing the current of the variable current source, the ON resistance of the fourth FET increases, and the impedance of the output load circuit can be increased. Thus, changes in the output characteristics of the power amplifier as a result of an increase in the temperature of the power amplifier element can be compensated for, and a degradation of the output characteristics of the power amplifier circuit can be suppressed.

(19) In the output load circuit according to (18), the variable current source is a PTAT current source.

With this configuration, the variable current that is proportional to the absolute temperature can be generated. Thus, under a high temperature environment, the impedance of the output load circuit can be increased.

(20) In the output load circuit according to (15), the fourth FET is connected between a first variable potential point and a reference potential point, and the second control circuit includes a constant current source that supplies a constant current to the first variable potential point, a first variable current source that is connected between the first variable potential point and a reference potential point, an operational amplifier circuit whose output terminal is connected to the gate of the fourth FET, whose non-inverted input terminal is connected to the first variable potential point, and whose inverted input terminal is connected to a second variable potential point that is different from the first variable potential point, a resistor that is connected between the second variable potential point and a reference potential point, and a second variable current source that supplies a second variable current to the second variable potential point.

With this configuration, by controlling at least one of the current flowing in the fourth FET and the current flowing in the resistor, the ON resistance of the fourth FET can be controlled. Specifically, by increasing at least one of the current of the first variable current source and the current of the second variable current source, the ON resistance of the fourth FET increases, and the impedance of the output load circuit can be increased. Thus, changes in the output characteristics of the power amplifier as a result of an increase in the temperature of the power amplifier element can be compensated for, and a degradation of the output characteristics of the power amplifier circuit can be suppressed.

(21) In the output load circuit according to (20), the first variable current source includes a current mirror circuit, and the second variable current source is a PTAT current source and supplies a variable current to an input of the current mirror circuit.

With this configuration, a second variable current that is proportional to the absolute temperature can be generated. Furthermore, a first variable current that is proportional to the variable current generated by the PTAT current source can be generated. Thus, under a high temperature environment, the impedance of the output load circuit can be increased.

(22) An attenuator circuit according to an aspect of the present disclosure includes an input/output circuit that is provided at a stage preceding a power amplifier, and a first control circuit that controls a gain of the input/output circuit. The input/output circuit includes at least a first resistor that is connected between an input terminal and an output terminal, and a first FET that is connected between the output terminal and a reference potential point of a fixed potential. The first control circuit includes a constant current source that supplies a constant current to a variable potential point, a variable current source that is connected between the variable potential point and a reference potential point, a second FET that is connected between the variable potential point and a reference potential point, an operational amplifier circuit whose output terminal is connected to a gate of the second FET, whose non-inverted input terminal is connected to the variable potential point, and whose inverted input terminal is connected to a fixed potential point that is different from the reference potential point, and a constant voltage source that applies a constant voltage to the fixed potential point.

With this configuration, by controlling the ON resistance of the second FET, the gate bias voltage of the first FET can be controlled. Thus, the insertion loss of the power amplifier can be controlled, and variations in the gain of the power amplifier caused by the temperature characteristics of the power amplifier element can be canceled out. Specifically, by controlling the current flowing in the second FET, the ON resistance of the second FET can be controlled. More specifically, by increasing the current of the variable current source, the ON resistance of the second FET increases. Thus, the ON resistance of the first FET increases, and the insertion loss of the power amplifier can be reduced.

(23) An attenuator circuit according to an aspect of the present disclosure includes an input/output circuit that is provided at a stage preceding a power amplifier, and a first control circuit that controls a gain of the input/output circuit. The input/output circuit includes at least a first resistor that is connected between an input terminal and an output terminal, and a first FET that is connected between the output terminal and a reference potential point of a fixed potential. The first control circuit includes a constant current source that supplies a constant current to a first variable potential point, a second FET that is connected between the first variable potential point and a reference potential point, an operational amplifier circuit whose output terminal is connected to a gate of the second FET, whose non-inverted input terminal is connected to the first variable potential point, and whose inverted input terminal is connected to a second variable potential point that is different from the first variable potential point, a second resistor that is connected between the second variable potential point and a reference potential point, and a variable current source that supplies a variable current to the second variable potential point.

With this configuration, by controlling the ON resistance of the second FET, the gate bias voltage of the first FET can be controlled. Thus, the insertion loss of the power amplifier can be controlled, and variations in the gain of the power amplifier caused by the temperature characteristics of the power amplifier element can be canceled out. Specifically, by controlling the current flowing in the second resistor, the ON resistance of the second FET can be controlled. More specifically, by increasing the current of the variable current source, the ON resistance of the second FET increases. Thus, the ON resistance of the first FET increases, and the insertion loss of the power amplifier can be reduced.

(24) An attenuator circuit according to an aspect of the present disclosure includes an input/output circuit that is provided at a stage preceding a power amplifier, and a first control circuit that controls a gain of the input/output circuit. The input/output circuit includes at least a first resistor that is connected between an input terminal and an output terminal, and a first FET that is connected between the output terminal and a reference potential point of a fixed potential. The first control circuit includes a constant current source that supplies a constant current to a first variable potential point, a first variable current source that is connected between the first variable potential point and a reference potential point, a second FET that is connected between the first variable potential point and a reference potential point, an operational amplifier circuit whose output terminal is connected to a gate of the second FET, whose non-inverted input terminal is connected to the first variable potential point, and whose inverted input terminal is connected to a second variable potential point that is different from the first variable potential point, a second resistor that is connected between the second variable potential point and a reference potential point, and a second variable current source that supplies a second variable current that is proportional to a first variable current flowing in the first variable current source to the second variable potential point.

With this configuration, by controlling the ON resistance of the second FET, the gate bias voltage of the first FET can be controlled. Thus, the insertion loss of the power amplifier can be controlled, and variations in the gain of the power amplifier caused by the temperature characteristics of the power amplifier element can be canceled out. Specifically, by controlling at least one of the current flowing in the second FET and the current flowing in the second resistor, the ON resistance of the second FET can be controlled. More specifically, by increasing at least one of the current of the first variable current source and the current of the second variable current source, the ON resistance of the second FET increases. Thus, the ON resistance of the first FET increases, and the insertion loss of the power amplifier can be reduced.

According to the present disclosure, an attenuator circuit and an output load circuit capable of suppressing a degradation of performance and compensating for variations in gain caused by temperature characteristics of a power amplifier element can be attained.

Furthermore, according to the present disclosure, an attenuator circuit and an output load circuit capable of compensating for changes in output characteristics of a power amplifier as a result of an increase in temperature of a power amplifier element and suppressing a degradation of the output characteristics of a power amplifier circuit can be attained.
1 attenuator circuit
2 power amplifier
3 output load circuit
2a drive-stage amplifier
2b power-stage amplifier
10 input/output circuit
11 first resistor
12 first FET
20 first control circuit
21 second FET
22 constant current source
23 variable current source (current mirror circuit)
23a first variable current source (current mirror circuit)
24 operational amplifier circuit
25 constant voltage source
26 PTAT current source
26a second variable current source (PTAT current source)
26b second variable current source (PTAT current source)
27 second resistor
30 output matching circuit
31 impedance matching circuit
32 third FET
40 second control circuit
41 fourth FET
42 constant current source
43 variable current source (current mirror circuit)
43a first variable current source (current mirror circuit)
44 operational amplifier circuit
45 constant voltage source
46 PTAT current source
46a second variable current source (PTAT current source)
46b second variable current source (PTAT current source)
47 second resistor
100, 100a power amplifier circuit
FV fixed potential point
GND reference potential point
VA variable potential point
VA1 first variable potential point
VA2 second variable potential point
VFB feedback potential
VREF potential

1. An attenuator circuit comprising:
an input/output circuit that is provided at a stage preceding a power amplifier circuit; and
a first control circuit that controls a gain of the input/output circuit,
wherein the input/output circuit includes at least
a first resistor that is electrically connected between an input terminal and an output terminal, and
a first FET that is electrically connected between the output terminal and a reference potential point,
wherein the first control circuit includes at least
a second FET that has an ON resistance that is substantially equal to an ON resistance of the first FET at a time when a gate bias voltage that is the same as a gate bias voltage of the first FET is applied, and
wherein a gate of the first FET and a gate of the second FET are electrically connected.

2. The attenuator circuit according to claim 1, wherein the power amplifier circuit is a power amplifier or a low noise amplifier.

3. The attenuator circuit according to claim 1,
wherein the second FET is connected between a variable potential point and a reference potential point, and
wherein the first control circuit includes
a constant current source that supplies a constant current to the variable potential point,
a variable current source that is electrically connected between the variable potential point and a reference potential point,
an operational amplifier circuit whose output terminal is electrically connected to the gate of the second FET, whose non-inverted input terminal is electrically connected to the variable potential point, and whose inverted input terminal is electrically connected to a fixed potential point, and
a constant voltage source that applies a constant voltage to the fixed potential point.

4. The attenuator circuit according to claim 3,
wherein the variable current source includes a current mirror circuit, and
wherein the first control circuit further includes
a PTAT current source that supplies a variable current to an input of the current mirror circuit.

5. The attenuator circuit according to claim 1,
wherein the second FET is electrically connected between a first variable potential point and a reference potential point, and
wherein the first control circuit includes
a constant current source that supplies a constant current to the first variable potential point,
an operational amplifier circuit whose output terminal is electrically connected to the gate of the second FET, whose non-inverted input terminal is electrically connected to the first variable potential point, and whose inverted input terminal is electrically connected to a second variable potential point that is different from the first variable potential point,
a second resistor that is electrically connected between the second variable potential point and a reference potential point, and
a variable current source that supplies a variable current to the second variable potential point.

6. The attenuator circuit according to claim 4,
wherein the variable current source is a PTAT current source.

7. The attenuator circuit according to claim 1,
wherein the second FET is electrically connected between a first variable potential point and a reference potential point, and
wherein the first control circuit includes
a constant current source that supplies a constant current to the first variable potential point,
a first variable current source that is electrically connected between the first variable potential point and a reference potential point,
an operational amplifier circuit whose output terminal is electrically connected to the gate of the second FET, whose non-inverted input terminal is electrically connected to the first variable potential point, and whose inverted input terminal is electrically connected to a second variable potential point that is different from the first variable potential point,
a second resistor that is electrically connected between the second variable potential point and a reference potential point, and
a second variable current source that supplies a second variable current to the second variable potential point.

8. The attenuator circuit according to claim 6,
wherein the first variable current source includes a current mirror circuit, and
wherein the second variable current source is a PTAT current source and supplies a variable current to an input of the current mirror circuit.

9. The attenuator circuit according to claim 1, further comprising:
an output matching circuit that is provided at a stage subsequent to the power amplifier circuit;
a capacitor and a third FET that are electrically connected in series between an output of the output matching circuit and a reference potential point; and
a second control circuit that controls an impedance of the output matching circuit,
wherein the second control circuit includes at least
a fourth FET that has an ON resistance that is substantially equal to an ON resistance of the third FET at a time when a gate bias voltage that is the same as a gate bias voltage of the third FET is applied, and
wherein a gate of the third FET and a gate of the fourth FET are electrically connected.

10. The attenuator circuit according to claim 8,
wherein the fourth FET is electrically connected between a variable potential point and a reference potential point, and
wherein the second control circuit includes
a constant current source that supplies a constant current to the variable potential point,
a variable current source that is electrically connected between the variable potential point and a reference potential point,
an operational amplifier circuit whose output terminal is electrically connected to the gate of the fourth FET, whose non-inverted input terminal is electrically connected to the variable potential point, and whose inverted input terminal is electrically connected to a fixed potential point, and
a constant voltage source that applies a constant voltage to the fixed potential point.

11. The attenuator circuit according to claim 9,
wherein the variable current source includes a current mirror circuit, and
wherein the second control circuit further includes
a PTAT current source that supplies a variable current to an input of the current mirror circuit.

12. The attenuator circuit according to claim 8,
wherein the fourth FET is electrically connected between a first variable potential point and a reference potential point, and
wherein the second control circuit includes
a constant current source that supplies a constant current to the first variable potential point,
an operational amplifier circuit whose output terminal is electrically connected to the gate of the fourth FET, whose non-inverted input terminal is electrically connected to the first variable potential point, and whose inverted input terminal is electrically connected to a second variable potential point that is different from the first variable potential point,
a resistor that is electrically connected between the second variable potential point and a reference potential point, and
a variable current source that supplies a variable current to the second variable potential point.

13. The attenuator circuit according to claim 11,
wherein the variable current source is a PTAT current source.

14. The attenuator circuit according to claim 8,
wherein the fourth FET is electrically connected between a first variable potential point and a reference potential point, and
wherein the second control circuit includes
a constant current source that supplies a constant current to the first variable potential point,
a first variable current source that is electrically connected between the first variable potential point and a reference potential point,
an operational amplifier circuit whose output terminal is electrically connected to the gate of the fourth FET, whose non-inverted input terminal is electrically connected to the first variable potential point, and whose inverted input terminal is electrically connected to a second variable potential point that is different from the first variable potential point,
a resistor that is electrically connected between the second variable potential point and a reference potential point, and
a second variable current source that supplies a second variable current to the second variable potential point.

15. The attenuator circuit according to claim 13,
wherein the first variable current source includes a current mirror circuit, and
wherein the second variable current source is a PTAT current source and supplies a variable current to an input of the current mirror circuit.

16. An output load circuit comprising:
an output matching circuit that is provided at a stage subsequent to a power amplifier circuit;
a capacitor and a third FET that are electrically connected in series between an output of the output matching circuit and a reference potential point; and
a second control circuit that controls an impedance of the output matching circuit,
wherein the second control circuit includes at least
a fourth FET that has an ON resistance that is substantially equal to an ON resistance of the third FET at a time when a gate bias voltage that is the same as a gate bias voltage of the third FET is applied, and
wherein a gate of the third FET and a gate of the fourth FET are electrically connected.

17. The output load circuit according to claim 16, wherein the power amplifier circuit is a power amplifier or a low noise amplifier.

18. The output load circuit according to claim 15,
wherein the fourth FET is electrically connected between a variable potential point and a reference potential point, and
wherein the second control circuit includes
a constant current source that supplies a constant current to the variable potential point,
a variable current source that is electrically connected between the variable potential point and a reference potential point,
an operational amplifier circuit whose output terminal is electrically connected to the gate of the fourth FET, whose non-inverted input terminal is electrically connected to the variable potential point, and whose inverted input terminal is electrically connected to a fixed potential point, and
a constant voltage source that applies a constant voltage to the fixed potential point.

19. The output load circuit according to claim 16,
wherein the variable current source includes a current mirror circuit, and
wherein the second control circuit further includes a PTAT current source that supplies a variable current to an input of the current mirror circuit.

20. The output load circuit according to claim 15,
wherein the fourth FET is connected between a first variable potential point and a reference potential point, and
wherein the second control circuit includes
a constant current source that supplies a constant current to the first variable potential point,
an operational amplifier circuit whose output terminal is electrically connected to the gate of the fourth FET, whose non-inverted input terminal is connected to the first variable potential point, and whose inverted input terminal is electrically connected to a second variable potential point that is different from the first variable potential point,
a resistor that is electrically connected between the second variable potential point and a reference potential point, and
a variable current source that supplies a variable current to the second variable potential point.

21. The output load circuit according to claim 18,
wherein the variable current source is a PTAT current source.

22. The output load circuit according to claim 15,
wherein the fourth FET is electrically connected between a first variable potential point and a reference potential point, and
wherein the second control circuit includes
a constant current source that supplies a constant current to the first variable potential point,
a first variable current source that is electrically connected between the first variable potential point and a reference potential point,
an operational amplifier circuit whose output terminal is electrically connected to the gate of the fourth FET, whose non-inverted input terminal is electrically connected to the first variable potential point, and whose inverted input terminal is electrically connected to a second variable potential point that is different from the first variable potential point,
a resistor that is electrically connected between the second variable potential point and a reference potential point, and
a second variable current source that supplies a second variable current to the second variable potential point.

23. The output load circuit according to claim 20,
wherein the first variable current source includes a current mirror circuit, and
wherein the second variable current source is a PTAT current source and supplies a variable current to an input of the current mirror circuit.
